(19) United States
(12) Patent Application Publication
(10) Pub. No.: US 2003/0193608 A1
(43) Pub. Date: Oct. 16, 2003

(54) Technique to manufacture a CIS module

(76) Inventor: Yung Chau Yen, San Jose, CA (US)

Correspondence Address: YUNG-CHAU YEN, Apt. 32D, 444 Saratoga Ave., Santa Clara, CA, 95050, US

(21) Appl. No.: 10/114,621

(22) Filed: Apr. 2, 2002

(51) Int. Cl. H01L 27/00; H04N 5/225

(52) U.S. Cl. 348/340; 250/208.1

(57) ABSTRACT

A new technique is provided to manufacture a CIS module by employing an alignment-plate, a light-guide plate, and a resolution plate. The above plates can be selected to be pre-fabricated into one piece to reduce the number of components for the CIS module. The dimension of resolution definition structures of resolution plate determines the resolution of CIS module and allows only the reflect light from the image with a desired resolution to pass through. Consequently, it alleviates the butting difficulty in the convention butting operation to form a linear sensor array. Also, a signal reading technique is provided to improve the photo-response of the conventional photo-sensing device. Therefore, operation speed is increased and product performance is improved.

### FIELD OF THE INVENTION

This invention relates to the field of the image sensing technology, particularly in a CIS (Contact Image Sensor) module manufacturing technique, including a technique to improve butting operation in CIS assembly and a technique to enhance reading photo-response of a photo-sensing element.

### PRIOR TECHNIQUE

Conventional CIS (Contact Image Sensor) module had the key components which were assembled as shown in FIG. 1 in a cross sectional view in the direction which was perpendicular to the length of the CIS module. On a PCB (Printed Circuits Board) substrate 100, there was a sensor chip array which was formed by butting IC (Integrated Circuits) sensor chip 101 to a desired length along the direction of the CIS module length. Consequently, the sensor chip array formed a linear sensor array to the desired full CIS module length. Each IC sensor chip 101 had the sensor array 102 which comprised of a series of photo-sensing elements. Conventionally, each of photo-sensing elements was photodiode or photo-transistor which is called CMOS image sensor. Of course, CCD (Charge Coupled Device) was also employed. The spacing from center to center of two neighboring photo-sensing elements determined the resolution of CIS module. Each photo-sensing element was also called pixel. The pixel size was determined by the resolution, which was defined by the number of dots per inch (dpi). For example, 200 dpi resulted in 5 mils pixel size. Other associated electronic circuits block 103 on PCB 100 was to convey an electrical signal to and from IC chip 101. The sensor array 102 was aligned to the rod lens 105. The rod lens comprised of an array of optical fibers 105-1, which were placed in sequential order and coated by the optically non-transmitted material 105-2 like black resin. Normally, each optical fiber or core of the rod lens 105-1 had a diameter much larger than the pixel dimension of the sensor array 102. A light source 106 had an array of a light-emitting device like LED (Light Emitting Diode) on another substrate 106-1 (typically PCB) to emit light 108-1 incident upon the image of document 104 through a sealing glass 109 with a uniform intensity along the module length. The image light (or reflective light from image) 108-2 passed through the core 105-1 of rod lens 105 to the sensor array 102 such that each pixel converted the image light into a photo-signal for further signal processing.

FIG. 2 showed the top horizontal view of a linear sensor chip array along the direction of the module length which comprised a series of same IC sensor chip 101-1 to 109-9. Each had a sensor array of same photo-sensing elements 102-1 to 102-9. There was a spacing 201 between two neighboring IC sensor chip 101 due to the butting operation. It can be seen that there are several drawbacks of the current CIS module manufacturing technique, including

(1) it is difficult to align IC chips to achieve a straight line of linear sensor array,

(2) it is difficult to control a uniform spacing between two neighboring sensor IC chips in sensor IC chip array during butting operations because of the equipment operational tolerance, particularly for the high resolution CIS module.

(3) it is very critical to align sensor array to rod lens. This alignment operation can easily affect the performance from one CIS module to another CIS module.

It is known that CMOS image sensor has a low sensitivity than CCD. How to improve CMOS sensor detection ability is constantly investigated. This invention will provide a technique to improve CMOS image sensor performance.

### SUMMARY OF INVENTION

It is the first object of this invention to provide a technique to eliminate the difficulty of the IC chip butting operation in CIS module assembly.

It is the second object of this invention to provide a technique that the CIS module resolution is not necessarily determined by the size of the photo-sensing element.

It is the third object of this invention to provide a technique that a CIS module can be more cost effectively assembled.

It is the forth object of this invention to provide a technique that different color signals from the same image can be detected simultaneously.

It is the fifth object of this invention to provide a technique to increase the operation speed of CIS module.

It is the sixth object of this invention to provide a technique to improve photo-signal reading for a given design of a photo-sensing element.

### BRIEF DESCRIPTION OF DRAWINGS

All drawings are not to scale, nor in exact shape and dimension, and location. The only purpose of drawings is to demonstrate the operational principle of this invention.

FIG. 1 shows the cross sectional view of key components in the conventional CIS module in a direction perpendicular to the CIS module length.

FIG. 2 shows the horizontal view of an linear sensor array along the module length direction which is perpendicular to the cross section as shown in FIG. 1.

FIG. 3 shows the arrangement of IC sensor chip array, alignment plate, light-guide plate and resolution plate and the cutting cross section along the center of the structures for each component.

FIG. 4 explains the operational principle of resolution structures of resolution plate when each of the resolution structures is a cavity.

FIG. 5 shows the cross sectional view of CIS module in a direction perpendicular to the CIS module length to demonstrate this invention which does not employ rod lens in CIS module assembly.

FIG. 6 shows a photo-signal reading technique in this invention by employing signal storage stages for repeatedly reading signal and reference storage stages which each reference storage stage stores a reference to be subtracted out from a signal to be read at each signal reading operation when the input signal is applied at the non-inverting terminal of operational amplifier.

FIG. 7 shows a photo-signal reading technique in this invention by employing signal storage stages for repeatedly reading signal and reference storage stages which each reference storage stage stores a reference to be subtracted out from a signal to be read at each signal reading operation when the input signal is applied at the inverting terminal of operational amplifier.

FIG. 8 shows a technique in this invention to improve the photo-response by employing multiple sensor array to repeatedly reading photo-signal of the same image.

### DETAILED DESCRIPTION OF INVENTION

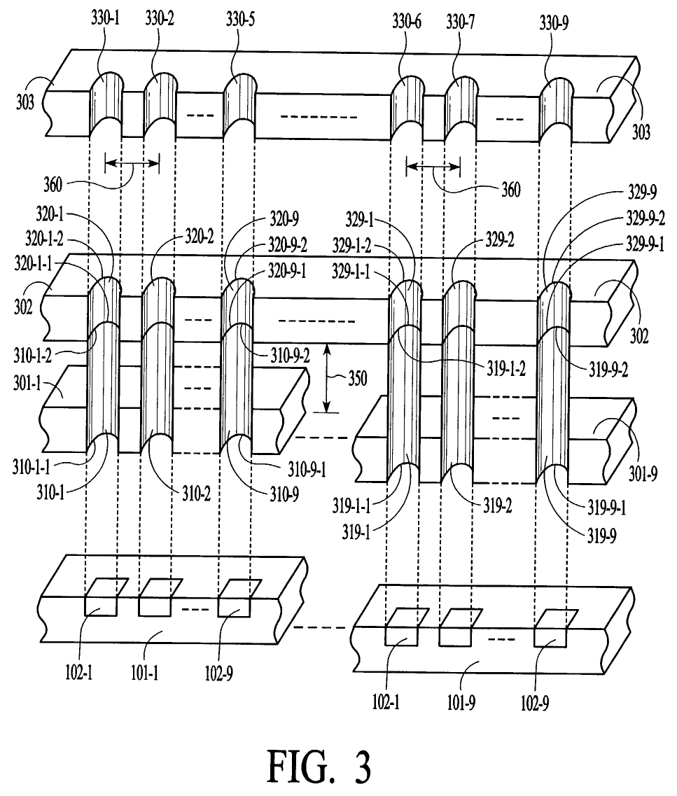

The fundamental operational principle of this invention to improve CIS module assembly is to employ alignment plate, light-guide plate and resolution plate so that the use of rod lens can be avoided. All alignment plate, light-guide plate and resolution plate are made with a material which is light non-transmissible except light-through structures in alignment plate, light-guide structures in light-guide plate and resolution definition structures in resolution plate. The configuration of three components is in such a manner that alignment plate is between sensor IC chip and light-guide plate which is between alignment plate and resolution plate which is between light-guide plate and line image which consists of a desired number of discrete images which are to be detected by a photo-sensing elements in a linear sensor array. Now, refereeing to FIG. 3, a linear sensor array is formed with a series of sensor arrays of photo-sensing elements from the first sensor array of first photo-sensing element 102-1 to last photo-sensing element 102-9 on first sensor chip 101-1 to last sensor array of first photo-sensing element 102-1 to last photo-sensing element 102-9 on last sensor IC chip 101 -9. In FIG. 3, the last sensor IC chip 101-9 is placed slightly off a linear line to show the advantages of this technique as described below. Each sensor array is aligned to light-through structures of an alignment plate in such a manner that the first photo-sensing element 102-1 of first array in first sensor IC chip 101-1 is aligned to first light-through structure 310-1 of first alignment plate 301-1, second photo-sensing element 102-2 is aligned to second light-through structure 310-2 of first alignment plate 301-1 to the last photo-sensing element 102-9 in first sensor IC chip 101-1 is aligned to last light-through structure 310-9 of first alignment plate 301-1 as shown in double-dot lines. Likewise, the first photo-sensing element 102-1 of last array on last sensor IC chip 101-9 is aligned to first light-through structure 319-1 of last alignment plate 301-9. Second photo-sensing element 102-2 is aligned to second light-through structure 319-2 of last alignment plate 301-9 and the last photo-sensing element 102-9 in last sensor IC chip 101-9 is aligned to last light-through structure 319-9 of last alignment plate 301-9. Similar to last sensor IC 101-9, last alignment plate 301-9 is also placed a slightly off linear line in order to align to last sensor array of last IC chip 101-9. This kind of alignment is called one-to-one alignment. Or it is called that the first sensor array 102-1 to 102-9 of first sensor IC chip 101-1 is one-to-one aligned to first light-through structures 310-1 to 310-9 of first alignment plate 301-1. Likewise, last sensor array 102-1 to 102-9 of last sensor IC chip 101-1 is one-to-one aligned to last light-through structures 319-1 to 319-9 of last alignment plate 301-9. Or light-through array of light-through structures from first alignment plate 301-1 to last alignment plate 301-9 is one-to-one aligned to linear sensor array. Light-through structures are one-to-one aligned to light-guide structures. The end of each light-through structure, which is aligned to each photo-sensing element in sensor array is called sensor end of light-through structure. The other end of light-through structure, which is aligned to light-guide structure is called light-guide end of light-through structure. Therefore, light-guide structures have light-through ends, which are aligned to light-through structures and resolution ends which are aligned to resolution-definition structures. Resolution-definition structures have light-guide ends, which are aligned to light-guide structures and image ends which are aligned to a line image. As shown in FIG. 3 the light-guide end of each aligned light-through structure and light-through end of each aligned light-guide structure are attached together at the light-through end of light-guide structure so that first light-guide structure 320-1 in light-guide plate 302 and first light-through structure 310-1 in first alignment plate 301-1 are integrated into a single piece from resolution end 320-1-2 through light end 320-1-1 of first light-guide structure 320-1 to the attached light-guide end of first light-through structures 310-1 in first alignment plate 301-1 to sensor end 310-1-1 of first light-through structure 310-1 in first alignment plate 301-1 till an aligned light-guide structure 329-1 in light-guide plate 302 and first light-through structure 319-1 of last alignment plate 301-9 are integrated into a single piece from resolution end 329-1-2 through light-through end 329-1-1 of an aligned light-guide structure 329-1 to the attached light-guide end 319-1-2 of first light-through structures 319-1 to sensor end 319-1-1 of first light-through structure 319-1 in last alignment plate 301-9. Likewise, other pairs of light-guide structure and respective light-through structure are integrated into a single component which is from resolution end of the respective light-guide structure to sensor end of respective light-through structure as shown in FIG. 3. Therefore, light-through structures of each alignment plate can be flexibly one-to-one aligned to respective sensor array. As shown in FIG. 3, the last alignment plate 301-9 can be easily aligned to last sensor chip 101-9 which is slightly placed off linear line. Now, light-guide array of light-guide structures from first light-guide structure 320-1 to last light-guide structure 329-9 in light-guide plate 301 is one-to-one aligned to resolution array of resolution-definition structures from first resolution-definition structure 330-1 to last resolution-definition structure 330-9 in resolution plate 303 as indicated by the double-dot lines in such a manner that first light-guide structure 320-1 is aligned to first resolution-definition structure 330-1, second light-guide structure 320-2 is aligned to second resolution-definition structure 330-2 till last light-guide structure 320-9-9 is aligned to last resolution-definition structure 330-9. A center-to-center spacing 360 between two neighboring resolution-definition structures is equal to a desired resolution of CIS module. In FIG. 3, both the image end and the light-guide end of each resolution-definition structure from first resolution-definition structure 330-1 to last resolution-definition structure 330-9 have same center-to-center spacing 360. If desired, the light-guide end can have a different spacing and a different dimension from the image end so that it can be much easier to manufacture light-guide structures, light-through structures and sensor chips. FIG. 3 shows the case that light-through structures and light-guide structures are attached by the extension of light-through structures by a length 350. This extension 350 can also be light-guide structures so that light-through structures and are light-guide structures are attached at light-guide ends of light-through structures. Or alignment plate and light-guide plate can be integrated into a single component such that the alignment section is made flexible, for example with plastic material, to be one-to-one aligned to each sensor IC chip. Those who are skillful in the field can easily modify to satisfy each application.

When rod lens are really desired to employ, line image is focused on image ends of resolution-definition structures. A conventional operation is followed. Since the center-to-center spacing between any two neighboring resolution-definition structures is equal to a desired resolution of CIS module, a reflective light from a discrete image of a desired resolution enters the aligned resolution-definition structure, then through the aligned light-guide structure which guide it to the aligned light-through structure to the aligned photo-sensing element which converts to a photo-signal which is read out for further signal processing.

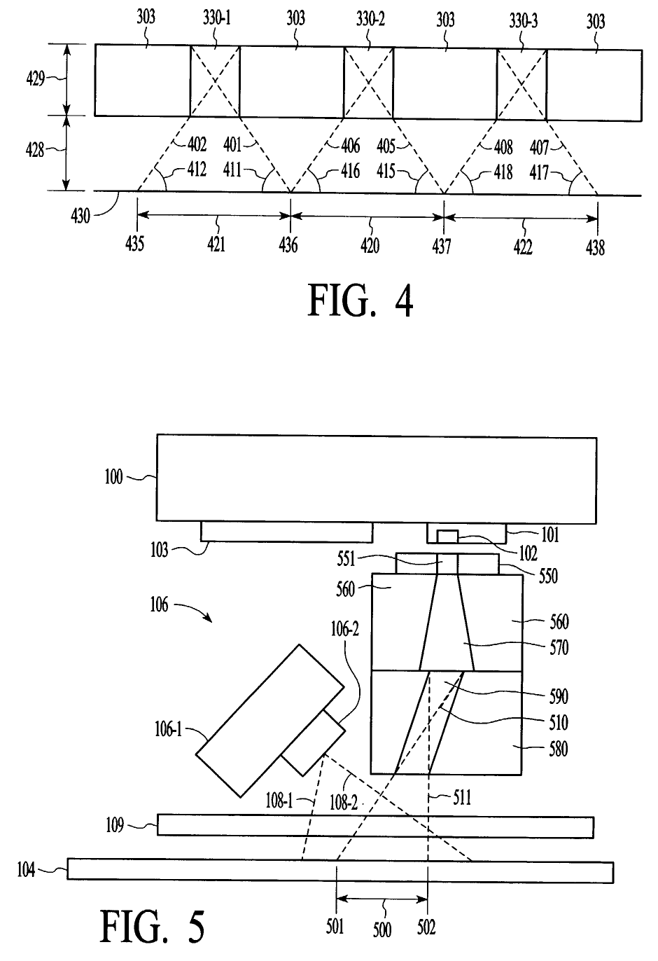

When each resolution-definition structure is in cavity structure, the operational principle of the resolution plate 303 can be described in FIG. 4. Only three neighboring resolution definition structures are used in FIG. 4 to explain the operational principle. The left resolution definition structure 330-1 is to collect the reflective light from the left image 421 which has the left edge 435 and the right edge 436 on the document 430 which this left resolution structure 330-1 is aligned to. The center resolution-definition structure 330-2 is to collect the reflective light from the center image 420 which has the left edge 436 and the right edge 437 on the document 430 which the center resolution definition structure 330-2 is aligned to. The right resolution definition structure 330-3 is to collect the reflective light from the right image 422 which has the left edge 437 and the right edge 438 on the document 430 which the right resolution definition structure 330-3 is aligned to. The three images have the same size of the desired resolution. The thickness 429 of the resolution plate 303 is determined by the separate spacing 428 between the resolution plate 303 and the document 430 in such a manner that the right edge 436 of the left image 421, the bottom right edge of the left resolution definition structure 330-1 and the top left edge of the left resolution definition structure 330-1 are formed in first right straight line 401. Likewise, the left edge 435 of the left image 421, the bottom left edge of the left resolution definition structure 330-1 and the top right edge of the left resolution structure 330-1 are formed in first left straight line 402. Similarly, the right edge 437 of the center image 420, the bottom right edge of the center resolution-definition structure 330-2 and the top left edge of the center resolution definition structure 330-2 are formed in second right straight line 405. The left edge 436 of the center image 420, the bottom left edge of the center resolution definition structure 330-2 and the top right edge of the center resolution structure 330-2 are formed in second left straight line 406. The right edge 438 of the right image 422, the bottom right edge of the right resolution definition structure 330-3 and the top left edge of the right resolution-definition structure 330-3 are formed in third right straight line 407. The left edge 437 of the right image 420, the bottom left edge of the right resolution definition structure 330-3 and the top right edge of the right resolution-structure 330-3 are formed in third left straight line 408. The first right straight line 401 and the surface of the document 430 form first right-side angle 411. The first left straight line 402 and the surface of the document 430 form first left-side angle 412. The second right straight line 405 and the surface of the document 430 form second right-side angle 415. The second left straight line 406 and the surface of the document 430 form second left-side angle 416. The third right straight line 407 and the surface of the document 430 form third right-side angle 417. The third left straight line 408 and the surface of the document 430 form third left-side angle 418. Since the resolution plate 303 and the document 430 are parallel, first right-side angle 411, second right-side angle 415, and third right-side angle 417 are equal in this example. When desired, resolution-definition structures are not perpendicular to line image, the left-side angle and right-side angle can be different. Likewise, first left-side angle 412, second left-side angle 416 and third left-side angle 418 are equal. The resolution plate 303 is made with a material which is light non-transmissible. Each surface of cavities 330-1,330-2 and 330-3 is made in such a manner that the reflective light is not reflected again. For example, it can be made very rough and not smooth. Therefore, only reflective light from the left image 421 larger than first right-side angle 411 and first left-side angle 412 can pass through left resolution structure 330-1. Likewise, only reflective light from the center image 420 larger than second right-side angle 415 and second left-side angle 416 can pass through center resolution structure 330-2. Only reflective light from the right image 422 larger than third right-side angle 417 and third left-side angle 418 can pass through center resolution structure 330-3. Any reflective light from neighboring image outside a desired image always forms a smaller angle than either left-side or right-side angle of the desired image. Therefore, there is no reflective light from any other neighboring image to pass through the cavity which is aligned to the desired image. For a fixed separate spacing 428, a desired resolution can be obtained by adjusting the dimension of the cavity of each resolution definition structure and the center-to-center spacing between two neighboring resolution definition structures. For a fixed dimension of the cavity, adjusting the separate spacing 428 and the center-to-center spacing between two neighboring resolution definition structures can obtain a desired resolution.

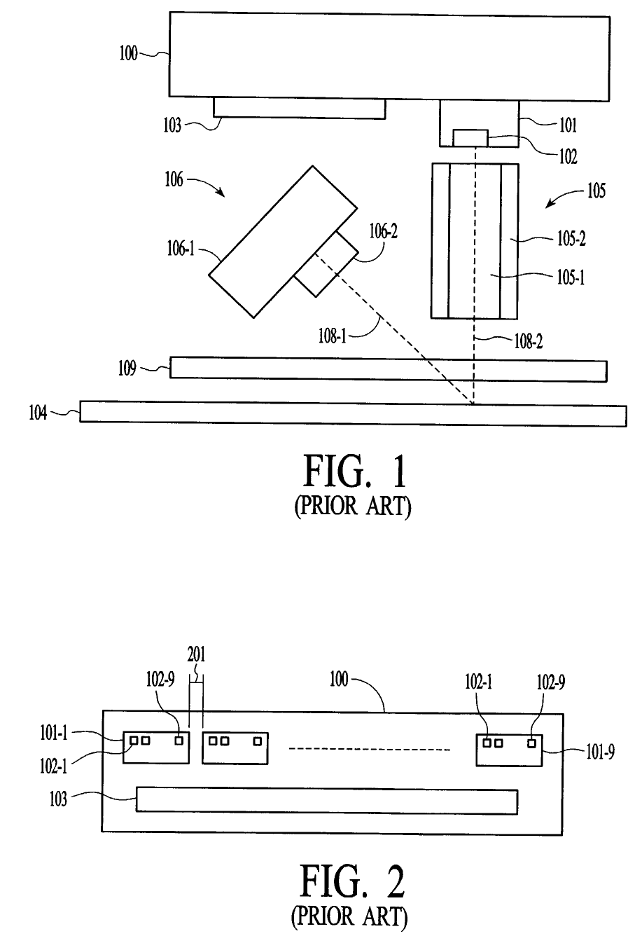

FIG. 5 shows a cross sectional view similar to FIG. 1, but the rod lens 105 is replaced with resolution plate 580, light-guide plate 560 and alignment plate 550. As explained in FIG. 4, for an image 500 which has the left edge 501 and the right edge 501, only the reflective light from the image 500 which has larger anger then defined by right line 511 and left line 510 can travel through the resolution-definition structures 590 to the light-guide structures 570 of the light-guide plate 560 which guide the reflective light to light-through structures 551 of alignment plate 550 to expose the reflective light onto sensor array 102 of sensor chip array 100. The advantages of this technique include that more arrays of resolution-definition structures can be employed to align to the same image such that these reflective lights enter one light-guide structure to guide these reflective lights incident on same photo-signal element to result in more photo-signal of this photo-sensing element, or a desired color patter is placed on a multiple resolution-definition structures which are aligned to the same image to result in a different color photo-signal simultaneously to increases the operation speed in the color application or multiple photo-signal from multiple linear sensor array of photo-sensing elements can be simultaneously read by employing multiple arrays of resolution-definition structures, light-guide structures and light-through structures to increase the operation speed in a mono color application. Or different color filters are placed or coated on multiple arrays of resolution-definition structures, different color photo-signal can be obtained at same time. Or the resolution plate, the light-guide plate or the alignment plate can be integrated into a single component to simplify the CIS module assembly. For those who are skillful in the field can easily modify it for each desired application.

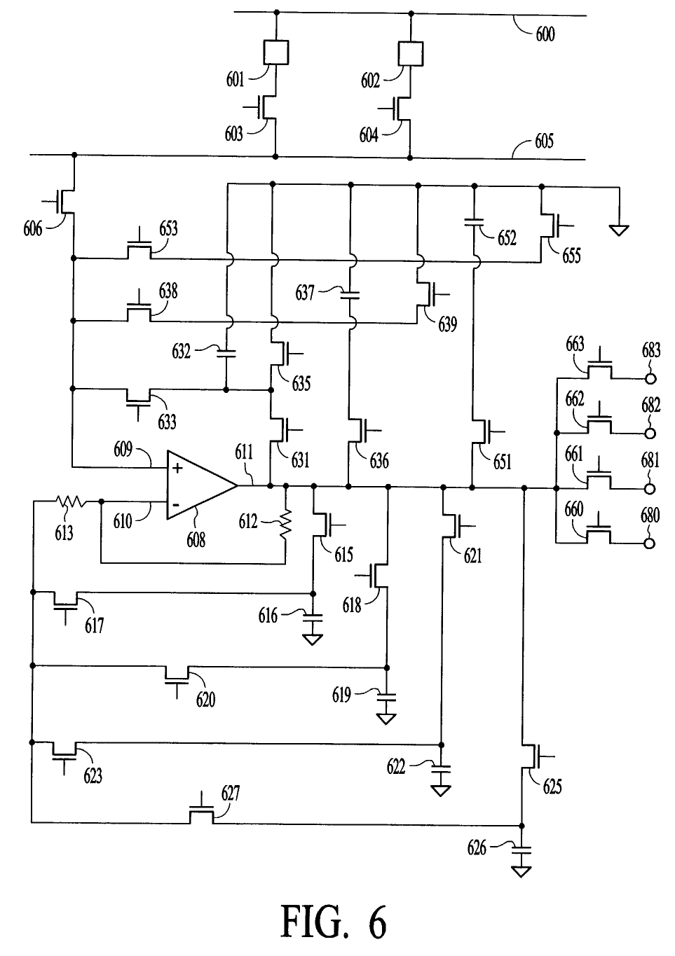

In the conventional CIS technology, the photo-signal of each pixel (photo-sensing element) in the sensor (pixel) array is read by applying a read pulse after a desired period of time of exposure to the light to achieve a desired photo-signal level. The exposure time limits the speed of CIS module operation, particularly for the low light level operation. A technique is provided here to enhance reading of the photo-signal with the conventional reading pulse. FIG. 6 shows one preferred embodiment of this invention which employs a reading circuits section which comprises amplifier circuits block, signal block, reference block and output block. An amplifier circuits block comprises operational amplifier 608 which has non-inverting input terminal 609, inverting input terminal 610 and output terminal 611, feedback resistor 612 and inverting input resistor 613. The ratio of feedback resistor 612 to inverting input resistor 613 determines the gain of this amplifier circuits block. In this example, the gain is set equal to 1, i.e., feedback resistor 612 and inverting input resistor 613 have same resistance. Signal block comprises a read signal storage stage and multiple enhanced read signal storage stages. Read signal is defined as when a signal is applied at input terminal, an output signal of operational amplifier 608 at output terminal 611 is a read signal. Therefore, reading photo-signal of a photo-sensing element results in read photo-signal at output terminal 611 of operational 608. Only two enhanced read signal storage stages are shown in FIG. 6. Each signal storage stage comprises a signal storage switch, signal storage device which is a capacitor in this example, stored signal reading switch and stored signal discharging switch. The stored signal reading switch is connected between non-inverting input terminal 609 and a common connection point of signal storage switch which is connected to output terminal 611 and signal storage capacitor which is connected to a common ground. Therefore, read signal storage stage comprises read signal storage switch 631, read signal storage capacitor 632, read signal reading switch 633 and read signal discharging switch 635. Likewise, first enhanced read signal storage stage comprises first enhanced read signal storage switch 636, first enhanced read signal storage capacitor 637, first enhanced read signal reading switch 638 and first enhanced read signal discharging switch 639. Second enhanced read signal storage stage comprises second enhanced read signal storage switch 651, second enhanced read signal storage capacitor 652, second enhanced read signal reading switch 653 and second enhanced read signal discharging switch 655. Reference block comprises multiple reference storage stages. Each reference storage stage stores a reference to be subtracted out from a signal to be read. Only four reference stages are shown in FIG. 6. Each reference storage stage comprises reference storage switch, reference storage device which is a capacitor in this example and reference reading switch. Therefore, first reference storage stage stores first reference (one reference) to be subtracted out from photo-signal at reading photo-signal operation. Reading photo-signal operation is defined as a photo-signal of a photo-sensing element is applied at input terminal of operational amplifier 608 to result in an output signal which is a read photo-signal at output terminal 611. First reference storage stage comprises first reference storage switch 615, first reference storage capacitor 616, and first reference reading switch 617. Second reference storage stage stores second reference (other reference) to be subtracted out from read photo-signal which is stored in read signal storage. Second reference storage stage comprises second reference storage switch 618, second reference storage capacitor 619, and second reference reading switch 620. Third reference storage stage stores third reference (another reference) to be subtracted out from first enhanced read photo-signal which is obtained from reading read photo-signal and stored in first enhanced read signal storage stage. Third reference storage stage comprises third reference storage switch 621, third reference storage capacitor 622, and third reference reading switch 623. Fourth reference storage stage stores fourth reference (further another reference) to be subtracted out from second enhanced read photo-signal which is obtained from reading first enhanced read photo-signal and stored in second enhanced read signal storage stage. Fourth reference storage stage comprises fourth reference storage switch 625, fourth reference storage capacitor 626, and fourth reference reading switch 627. In each reference storage stage, reference reading switch is connected between inverting input resistor 613 and a common connection point of reference storage switch which is connected to output terminal 611 and reference storage capacitor which is connected to a common ground as shown in FIG. 6. Output block comprises multiple output stages. Four output stages are shown in FIG. 6. Each output stage comprises an output post and an output switch which is connected between output terminal 611 and output post. First output stage comprises first output switch 660 and first output post 680. Likewise, second output stage comprises second output switch 661 and second output post 681. Third output stage comprises third output switch 662 and third output post 682. Fourth output stage comprises fourth output switch 663 and fourth output post 683. In this example, first output stage is designed to transfer read photo-signal. Second output stage is designed to transfer first enhanced read photo-signal. Third output stage is designed to transfer second enhanced read photo-signal. Fourth output stage is designed to transfer third enhanced read photo-signal. There is also photo-signal reading switch 606 which is connected between non-inverting terminal and a common line 605 of multiplexing switches which comprises first signal switch 603, second signal switch 604. Only two photo-sensing elements of linear sensor array are shown in FIG. 6 to explain the operational principle. The first signal switch 603 is connected between first photo-sensing element 601 and a common line 605. The second signal switch 604 is connected between second photo-sensing element 602 and a common line 605.In case that a parallel dump operation is designed to transfer a photo-signal of each photo-sensing element in a linear sensor array to a respective storage device, these signal switch is connected to respective storage device. But the operation described below is still applied.

Now, the operation of FIG. 6 can be described below. It comprises the steps of:

(1) storing first reference which is used to be subtracted out from reading a photo-signal of a photo-sensing element by turning on photo-signal reading switch 606 and first reference storage switch 615. Therefore, first reference from common line 605 to output terminal 611 is stored into first reference storage capacitor 616,

(2) storing read signal noise by turning on photo-signal reading switch 606, first reference reading switch 617 and read signal storage switch 631. Therefore, read signal noise is stored into read signal storage capacitor 632.

(3) Storing second reference which is used to be subtracted out from reading read signal which is stored in read signal storage capacitor 632 by turning on read signal reading switch 633 and second reference storage switch 618. Therefore, second reference is stored into second reference storage capacitor 619.

(4) storing first enhanced read signal noise by turning on read signal reading switch 633, second reference reading switch 620 and first enhanced read signal storage switch 636. Therefore, first enhanced read signal noise is stored into first enhanced read signal storage capacitor 637.

(5) Storing third reference which is used to be subtracted out from reading first enhanced read signal which is stored in first enhanced read signal storage capacitor 637 by turning on first enhanced read signal reading switch 638 and third reference storage switch 621. Therefore, third reference is stored into third reference storage capacitor 622.

(6) storing second enhanced read signal noise by turning on first enhanced read signal reading switch 638, third reference reading switch 623 and second enhanced read signal storage switch 651. Therefore, second enhanced read signal noise is stored into second enhanced read signal storage capacitor 652.

(7) Storing fourth reference which is used to be subtracted out from reading second enhanced read signal which is stored in second enhanced read signal storage capacitor 652 by turning on second enhanced read signal reading switch 653 and fourth reference storage switch 625. Therefore, fourth reference is stored into fourth reference storage capacitor 626.

(8) Discharging all charges in read signal storage capacitor 633, first enhanced read signal storage capacitor 638 and second enhanced read signal storage capacitor 653 by turning on read signal discharge switch 635, first enhanced read signal discharge switch 639 and second enhanced read signal discharge switch 655 respectively.

(9) now, reading photo-signal of photo-sensing elements in linear sensor array sequentially with no light exposure to linear sensor array by first turning on first signal switch 603 of multiplexing switches, photo-signal reading switch 606,first reference reading switch 617, read signal storage switch 631 and first output switch 660. Therefore, dark signal of first photo-sensing element 601 is sent out to output post 680 and simultaneously stored into read signal storage capacitor 632.

(10) reading dark signal by turning on read signal reading switch 633, second reference reading switch 620, first enhanced read signal storage switch 636 and second output switch 661 to obtain first enhanced dark signal. Therefore, first enhanced dark signal is sent out to second output post 681 and simultaneously stored into first enhanced read signal storage capacitor 637.

(11) reading first enhanced dark signal by turning on first enhanced read signal reading switch 638, third reference reading switch 623, second enhanced read signal storage switch 651 and third output switch 662 to obtain second enhanced dark signal. Therefore, second enhanced dark signal is sent out to third output post 682 and simultaneously stored into second enhanced read signal storage capacitor 652.

(12) reading second enhanced dark signal by turning on second enhanced read signal reading switch 653, fourth reference reading switch 627 and fourth output switch 663 to obtain third enhanced dark signal. Therefore, third enhanced dark signal is sent out to fourth output post 683. This completes reading dark signal of first photo-sensing element.

(13) discharging all charges in read signal storage capacitor 633, first enhanced read signal storage capacitor 638 and second enhanced read signal storage capacitor 653 by turning on read signal discharge switch 635, first enhanced read signal discharge switch 639 and second enhanced read signal discharge switch 655 respectively.

(14) repeating step 9 to 13 to obtain dark signal, first enhanced dark signal, second enhanced dark signal and third enhanced dark signal of second photo-sensing element 602 and continuing on to complete reading operation for last photo-sensing element in linear sensor array.

(15) exposing light to linear sensor array at a desired intensity level for a desired period of time.

(16) now, reading photo-signal of photo-sensing elements in linear sensor array sequentially by first turning on first signal switch 603 of multiplexing switches, photo-signal reading switch 606, first reference reading switch 617, read signal storage switch 631 and first output switch 660. Therefore, light signal which is read photo-signal of first photo-sensing element 601 is sent out to output post 680 and simultaneously stored into read signal storage capacitor 632.

(17) reading light signal by turning on read signal reading switch 633, second reference reading switch 620, first enhanced read signal storage switch 636 and second output switch 661 to obtain first enhanced light signal. Therefore, first enhanced light signal is sent out to second output post 681 and simultaneously stored into first enhanced read signal storage capacitor 637.

(18) reading first enhanced light signal by turning on first enhanced read signal reading switch 638, third reference reading switch 623, second enhanced read signal storage switch 651 and third output switch 662 to obtain second enhanced light signal. Therefore, second enhanced light signal is sent out to third output post 682 and simultaneously stored into second enhanced read signal storage capacitor 652.

(19) reading second enhanced light signal by turning on second enhanced read signal reading switch 653, fourth reference reading switch 627 and fourth output switch 663 to obtain third enhanced light signal. Therefore, third enhanced light signal is sent out to fourth output post 683. This completes reading light signal of first photo-sensing element.

(20) discharging all charges in read signal storage capacitor 633, first enhanced read signal storage capacitor 638 and second enhanced read signal storage capacitor 653 by turning on read signal discharge switch 635, first enhanced read signal discharge switch 639 and second enhanced read signal discharge switch 655 respectively.

(21) repeating step 16 to 20 to obtain light signal, first enhanced light signal, second enhanced light signal and third enhanced light signal of second photo-sensing element 602 and continuing on to complete reading last photo-sensing element in linear sensor array.

(22) obtaining photo-response which is equal to light signal minus dark signal, first enhanced photo-response which is equal to first enhanced light signal minus first enhanced dark signal, second enhanced photo-response which is equal to second enhanced light signal minus second enhanced dark signal, third enhanced photo-response which is equal to third enhanced light signal minus third enhanced dark signal.

(23) obtaining total photo-response which can be one of photo-response, first enhanced photo-response, second enhanced photo-response, third enhanced photo-response, or sum of any selected number of items from photo-response, first enhanced photo-response, second enhanced photo-response and third enhanced photo-response for each photo-sensing element.

The above process is set up for a case that dark signal, first enhanced dark signal, second enhanced dark signal and third enhanced dark signal are read out for each photo-sensing element to obtain photo-response, first enhanced photo-response, second enhanced photo-response and third enhanced photo-response respectively. Many other methods can be used to obtain photo-response with the use of FIG. 6. For example, dark photo-signal, including first reference in the above process, of each photo-sensing element is stored into each storage capacitor in such a manner that first dark photo-signal of first photo-sensing element is used to be subtracted out from reading first light level of first photo-sensing element to obtain photo-response of first photo-sensing element, Second dark photo-signal of second photo-sensing element is used to be subtracted out from reading second light level of second photo-sensing element to obtain photo-response of second photo-sensing element and continue on to last dark photo-signal of last photo-sensing element is used to be subtracted out from reading last light level of last photo-sensing element to obtain photo-response of last photo-sensing element. Or either first dark signal including first reference, or a mean value of selected number of dark signals which either include or not include first reference is stored into first reference storage stage for reading photo-signal of a photo-sensing element. Those who are skillful in the field can modify the use of a selection of references for each desired application.

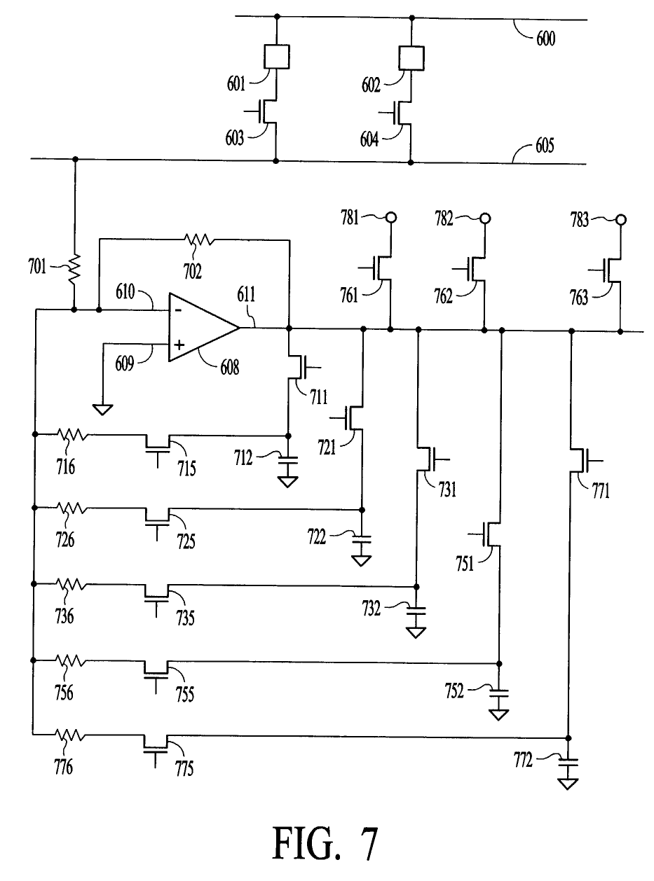

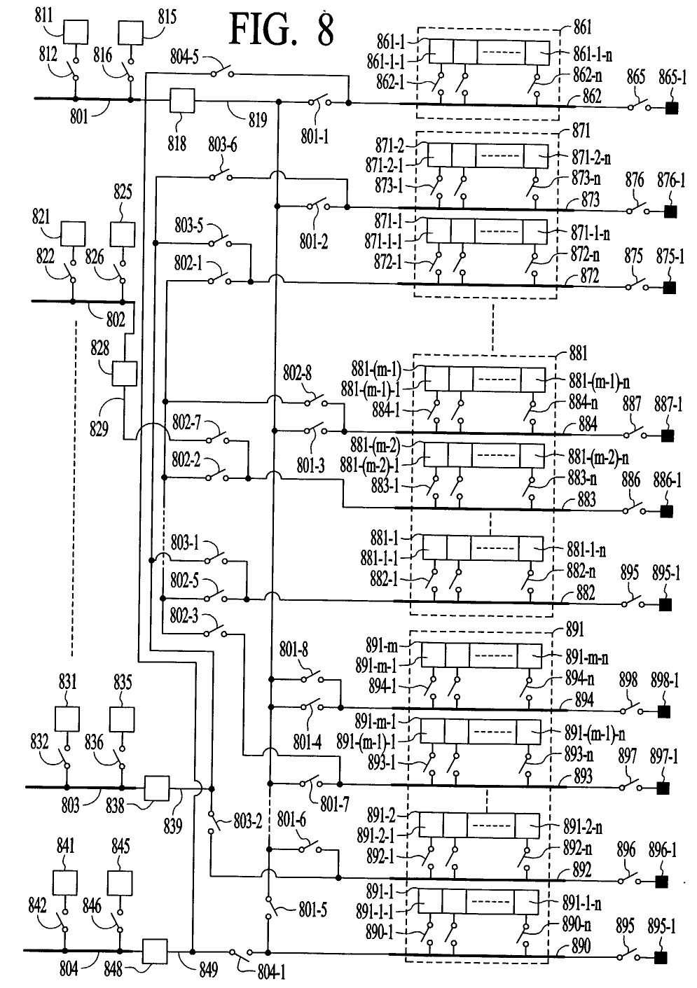

FIG. 6 shows a preferred embodiment that when a photo-signal of a photo-sensing element is applied at non-inverting input terminal of operational amplifier. This technique can be equally well applied when a photo-signal of a photo-sensing element is applied at inverting input terminal of operational amplifier. It can be described in FIG. 7. Both reference block and signal block are connected between output terminal 611 and inverting input terminal 610. Only three reference stages and two signal storage stages are as an example to describe the operational principle of this technique shown in FIG. 7. Now, in amplifier circuits block, non-inverting input terminal 609 is connected to a common ground. There is no photo-signal reading switch. Feedback resistor 702 is connected between output terminal 611 and inverting input terminal 610. An input resistor is connected to inverting input terminal 610 for reading photo-signal and for reading each stored reference in reference block and each stored signal in signal block. Therefore, photo-signal reading input resistor 701 is connected between a common line 605 and inverting input terminal 610. In reference block, first reference storage stage comprises of first reference storage switch 711 which is connected to output terminal 611, first reference storage device (capacitor) 712 which is connected to a common ground, first reference reading switch 715 which is connected between a common connection point of first reference storage switch 711 and first reference storage capacitor 712 and first reference input resistor 716 which is connected between inverting input terminal 610 and first reference reading switch 715. Second reference storage stage comprises of second reference storage switch 721 which is connected to output terminal 611, second reference storage capacitor 722 which is connected to a common ground, second reference reading switch 725 which is connected between a common connection point of second reference storage switch 721 and second reference storage capacitor 722 and second reference input resistor 726 which is connected between inverting input terminal 610 and second reference reading switch 725. Third reference storage stage comprises of third reference storage switch 731 which is connected to output terminal 611, third reference storage capacitor 732 which is connected to a common ground, third reference reading switch 735 which is connected between a common connection point of third reference storage switch 731 and third reference storage capacitor 732 and third reference input resistor 736 which is connected between inverting input terminal 610 and third reference reading switch 735. In signal block, read signal storage stage comprises of read signal storage switch 751 which is connected to output terminal 611, read signal storage capacitor 752 which is connected to a common ground, read signal reading switch 755 which is connected between a common connection point of read signal storage switch 751 and read signal storage capacitor 752 and read signal reading input resistor 756 which is connected between inverting terminal 610 and read signal reading switch 755. First enhanced read signal storage stage comprises of first read signal storage switch 771 which is connected to output terminal 611, first read signal storage capacitor 772 which is connected to a common ground, first enhanced read signal reading switch 775 which is connected between a common connection point of first enhanced read signal storage switch 771 and first enhanced read signal storage capacitor 772 and first enhanced read signal reading input resistor 776 which is connected between inverting terminal 610 and first enhanced read signal reading switch 775. Similar to FIG. 6, first reference is subtracted out from photo-signal at reading photo-signal operation. Second reference is subtracted out from read photo-signal at reading read photo-signal operation. Third reference is subtracted out from first enhanced read photo-signal at reading first enhanced read photo-signal operation. Although many method can be applied to run operation of FIG. 7, only one method is described here. The ratio of feedback resistor 702 to each reference reading input resistor 716, or 726, or 736 is designed to be equal to 1. Those who are skillful in the field can easily modify to satisfy each desired application. Now, first reference is stored into first reference storage capacitor 712 by turning on first signal switch 603 and first reference storage switch 711. Second reference is stored into second reference storage capacitor 722 by turning on first signal switch 603, read signal storage switch 751 and first reference reading switch 715, followed by turning on read signal reading switch 755 and second reference storage switch 721. Third reference is stored into third reference storage capacitor 732 by turning on read signal reading switch 755, second reference reading switch 725, first enhanced read signal storage switch 771, followed by turning on first enhanced read signal reading switch 775 and third reference storage switch 731. After third reference is stored into third reference storage capacitor 732, both signals in read signal storage capacitor 752 and first enhanced read signal storage capacitor 772 are cleared by turning on read signal storage switch 751 and first enhanced read signal storage switch 771 through low output resistance of operational amplifier 608. Of course, a discharging switch can be connected across these two capacitors to clear signals. Here, dark photo-signal, including first reference described in FIG. 6, of first photo-sensing element 601 is used as first reference for each photo-sensing element at reading light signal of photo-sensing element. As described in FIG. 6, mean dark photo-signal can be also used as first reference. After linear sensor array of photo-sensing elements is exposed to light at a desired intensity level for a period of time, photo-response of first photo-sensing element is obtained by turning on first signal switch 603, first reference reading switch 715, read signal storage switch 751, and first output switch 761. Therefore, photo-response of first photo-sensing element is sent out to first output post 781 and simultaneously stored into read signal storage capacitor 752. Here, photo-response is equal to light signal minus dark signal which is first reference. First enhanced photo-response is obtained by turning on second reference reading switch 725, first enhanced read signal switch 755, first enhanced storage switch 771 and second output switch 762. Therefore, first enhanced photo-response sent out to second output post 782 and simultaneously stored into first enhanced read signal storage capacitor 772. Second enhanced photo-response is obtained by turning on third reference reading switch 735, second enhanced read signal switch 775 and third output switch 763. Therefore, second enhanced photo-response sent out to third output post 783. Total photo-response can be photo-response, or first enhanced photo-response, or second enhanced photo-response or sum of selected items from photo-response, first enhanced photo-response and second enhanced photo-response. After completion of reading of first photo-sensing element, all charges in read signal storage capacitor 752 and first enhanced read signal storage capacitor 772 are cleared. Then, the same process steps of reading first photo-sensing element are repeated to obtain total photo-response of each photo-sensing element from second photo-sensing element to last photo-sensing element of linear sensor array.

Another improved technique to obtain photo-response of a photo-sensing element to detect a line image is shown in FIG. 8. It employs multiple linear sensor arrays. Basically, this technique employs 2D-array (2 dimensional array) to improve photo-signal reading of an image in a line image detection application. This technique comprises five sections which are devices section, signal storage device section, initial set-up switch section, signal reading switch section and output section. In device section, it comprises multiple linear sensor arrays, signal switch and output circuit block. Therefore, as shown in FIG. 8, first linear sensor array consists of first photo-sensing element 811, second photo-sensing element 815 and on to a desired number of photo-sensing elements in first linear sensor array. First signal switch 812 of first linear sensor array is connected between first photo-sensing element 811 and first common line 801. Likewise, second signal switch 816 of first linear sensor array is connected between second photo-sensing element 815 and first common line 801 and so on for the rest signal switches in first linear sensor array. Of course, the center-to-center spacing between any two neighboring photo-sensing elements is equal to a desired resolution to detect a discrete image in a line image. First common line 801 is connected to first output circuit block 818 which is a typical output reading circuit in conventional CIS module to convey a photo-signal out for a signal processing. Similarly, second linear sensor array consists of first photo-sensing element 821, second photo-sensing element 825 and on to a desired number of photo-sensing elements in second linear sensor array. First signal switch 822 of second linear sensor array is connected between first photo-sensing element 821 and second common line 802. Likewise, second signal switch 826 of second linear sensor array is connected between second photo-sensing element 825 and second common line 802 and so on for the rest signal switches in second linear sensor array. Second common line 802 is connected to second output circuit block 828 which is a typical output reading circuit like first output circuit block 818 in conventional CIS module to convey a photo-signal out for a signal processing. It continues on as shown with a dotted line to one before last linear sensor array which consists of first photo-sensing element 831, second photo-sensing element 835 and on to a desired number of photo-sensing elements in one before last linear sensor array as shown in FIG. 8. First signal switch 832 of one before last linear sensor array is connected between first photo-sensing element 831 and one before last common line 803. Likewise, second signal switch 836 of second linear sensor array is connected between one before last photo-sensing element 835 and one before last common line 803 and so on for the rest signal switches in one before last linear sensor array. One before last common line 803 is connected to one before last output circuit block 838 which is a typical output reading circuit in conventional CIS module to convey a photo-signal out for further signal processing. Finally, last linear sensor array consists of first photo-sensing element 841, second photo-sensing element 845 and on to a desired number of photo-sensing elements in last linear sensor array. First signal switch 842 of last linear sensor array is connected between first photo-sensing element 841 and last common line 804. Likewise, second signal switch 846 of last linear sensor array is connected between second photo-sensing element 835 and last common line 804 and so on for the rest signal switches in last linear sensor array. Last common line 804 is connected to last output circuit block 848 which is a typical output reading circuit in conventional CIS module to convey a photo-signal out for a signal processing. In signal storage device section, there are signal storage switch and signal storage device to store each read photo-signal of a photo-sensing element in multiple linear sensor arrays. This signal storage device can be a simple storage capacitor, any conventional memory device such as DRAM(Dynamic Random Access Memory). SRAM(Static Random Access Memory), EPROM(Electrical Programmable Read Only Memory), EEPROM (Electrical Erasable Read Only Memory), or magnetic storage devices etc. A desired number of signal storage devices form a signal storage array. One signal storage array contains at least the same number of signal storage devices as the number of photo-sensing elements of a linear sensor array whose photo-signals are to be stored into this signal storage array. A desired number of signal storage array form a signal storage group. One signal storage group contains at least the same number of signal storage arrays as the number of linear sensor array whose photo-signals of photo-sensing elements are to be stored into respective signal storage devices of respective signal storage array. The number of signal storage groups is at least equal to the number of linear sensor arrays in multiple linear sensor arrays. The number of signal storage groups and the number of storage devices in each signal storage array can be different. As shown in FIG. 8, first signal storage group 861 consists of one signal storage array 861-1 which consists of a series of signal storage device from first signal storage device 861-1-1 to last signal storage device 861-1-n. First signal storage switch 862-1 is connected between first signal storage device 861-1-1 in first signal storage array 861-1 and first signal reading line 862. It continues on to last signal storage switch 862-n which is connected between last signal storage device 861-1-n in first signal storage array 861-1 and first signal reading line 862. Second signal storage group 871 consists of first signal storage array 871-1 and second signal storage array 871-2. First signal storage array 871-1 consists of a series of signal storage device from first signal storage device 871-1-1 to last signal storage device 871-1-n. First signal storage switch 872-1 is connected between first signal storage device 871-1-1 in first signal storage array 871-1 and first signal reading line 872. It continues on to last signal storage switch 872-n which is connected between last signal storage device 871-1-n in first signal storage array 871-1 and first signal reading line 872. Likewise, second signal storage array 871-2 consists of a series of signal storage device from first signal storage device 871-2-1 to last signal storage device 871-2-n. First signal storage switch 873-1 is connected between first signal storage device 871-2-1 in second signal storage array 871-2 and second signal reading line 873. It continues on as shown with a dotted line to last signal storage switch 873-n which is connected between last signal storage device 871-2-n in second signal storage array 871-2 and second signal reading line 873. It continues on to one before last signal storage group 881 as shown in FIG. 8. One before last signal storage group 881 consists of multiple signal storage arrays from first signal storage array 881-1 to one before last signal storage array 881-(m-1). Similar to first signal storage group 861 and second signal storage group 871, first signal storage array 881-1 consists of a series of signal storage devices from first signal storage device 881-1-1 to last signals storage device 881-1-n. The first signal switch 882-1 of first signal storage array 881-1 is connected between first signal storage device 881-1-1 and first signal reading line 882 of one before last signal storage group 881 and on to last signal switch 882-n which is connected between last signal storage device 881-1-n and fist signal reading line 882. As shown in FIG. 8, it continues to two before last signal storage array 881-(m-2) which consists of a series of signal storage devices from first signal storage device 881-(m-2)-1 to last signals storage device 881-(m-2)-n. In two before last signal storage array 88 1-(m-2), first signal storage switch 881-(m-2)-1 is connected between first signal storage device 881-(m-2)-1 and two before last signal reading line 883 and on to last signal storage switch 881-(m-2)-n which is connected between last signal storage device 881-(m-2)-n and two before last signal reading line 883. One before last signal storage array 881-(m-1) consists of a series of signal storage devices from first signal storage device 881-(m-1)-1 to last signals storage device 881-(m-1)-n. In one before last signal storage array 881-(m-1), first signal storage switch 881-(m-1)-1 is connected between first signal storage device 88 1-(m-1)-1 and one before last signal reading line 884 and on to last signal storage switch 88 1-(m-1)-n which is connected between last signal storage device 88 1-(m-1)-n and one before last signal reading line 883. Finally, last signal storage group 891 consists of other multiple signal storage arrays from first signal storage array 891-1 to last signal storage array 891-(m-1). Similar to the description of one before last signal storage group 881, first signal storage array 891-1 consist of a series of signal storage devices from first signal storage device 891-1-1 to last signal storage device 891-1-n. First signal storage switch 890-1 of first signal storage array 891-1 is connected between first signal storage device 891-1-1 and first signal reading line 890 and on to last signal storage switch 890-n which is connected between last signal storage device 891-1-n and first signal reading line 890. Second signal storage array 891-2 consist of a series of signal storage devices from first signal storage device 891-2-1 to last signal storage device 891-2-n. First signal storage switch 892-1 of second signal storage array 891-2 is connected between first signal storage device 891-2-1 and second signal reading line 892 and on to last signal storage switch 892-n which is connected between last signal storage device 891-2-n and second signal reading line 892. It continues on as shown with dotted line to one before last signal storage array 891-(m-1) which consists of a series of signal storage devices from first signal storage device 89 1-(m-1)-1 to last signal storage device 891-(m-1)-n. First signal storage switch 893-1 of one before last signal storage array 891-(m-1) is connected between first signal storage device 891-(m-1)-1 and one before last signal reading line 892 and on to last signal storage switch 893-n which is connected between last signal storage device 891-(m-1)-n and one before last signal reading line 893. Finally, last signal storage array 891-m consists of a series of signal storage devices from first signal storage device 891-m-1 to last signal storage device 891-m-n. First signal storage switch 894-1 of last signal storage array 891-m is connected between first signal storage device 891-m-1 and last signal reading line 894 and on to last signal storage switch 894-n which is connected between last signal storage device 891-m-n and last signal reading line 894. In output section, there is output switch which is connected between signal reading line and output post. Therefore, first output switch 865 is connected between first signal reading line 862 and first output post 865-1 in first signal storage group 861. In second signal storage group, first output switch 875 is connected between first signal reading line 872 and first output post 875-1 and second output switch 876 is connected between second signal reading line 873 and second output post 876-1. Likewise, in one before last signal storage group 881, first output switch 885 is connected between first signal reading line 882 and first output post 885-1 and so on to one before last output switch 886 which is connected between one before last signal reading line 883 and one before last output post 886-1. In last signal storage group 891, first output switch 895 is connected between first signal reading line 890 and first output post 895-1, second output switch 896 is connected between second signal reading line 892 and second output post 896-1 and so on to one before last output switch 897 which is connected between one before last signal reading line 893 and one before last output post 897-1.Finally, last output switch 898 is connected between last signal reading line 894 and last output post 898-1. In initial set-up switch section, there is an initial set-up switch which is connected between signal line from output circuit block in device section and signal reading line of signal storage array in signal storage group. An initial set-up switch is called first initial set-up switch when it is connected to first signal line 819 which is connected to first output circuit block 818. Therefore, an initial set-up switch is called second initial set-up switch when it is connected to second signal line 829 which is connected to second output circuit block 828. An initial set-up switch is called one before last initial set-up switch when it is connected to one before last signal line 839 which is connected to one before last output circuit block 838 and an initial set-up switch is called last initial set-up switch when it is connected to last signal line 849 which is connected to last output circuit block 848. Therefore, an initial set-up switch is connected in such a manner that there is one first initial set-up switch which is connected to one signal reading line from first signal storage group 861 to last signal storage group 891, there is one second initial set-up switch which is connected to one different signal reading line from second signal storage group 871 to last signal storage group 891, there is one third initial set-up switch which is connected to one other different signal reading line from one before last signal storage group 881 to last signal storage group 891 and there is one fourth initial set-up switch which is connected to one another different signal reading line in last signal storage group 891. Consequently, one of first initial set-up switch 801-1 is connected between first signal line 819 and first signal reading line 862 in first signal storage group 861. Other one of first initial set-up switch 801-2 is connected between first signal line 819 and second signal reading line 873 in second signal storage group 871. Another one of first initial set-up switch 801-3 is connected between first signal line 819 and one before last signal reading line 884 in one before last signal storage group 881. Further another one of first initial set-up switch 801-4 is connected between first signal line 819 and last signal reading line 894 in last signal storage group 891. One of second initial set-up switch 802-1 is connected between second signal line 829 and first signal reading line 872 in second signal storage group 871. Other one of second initial set-up switch 802-2 is connected between second signal line 829 and two before last signal reading line 883 in one before last signal storage group 881. Another one of second initial set-up switch 802-3 is connected between second signal line 829 and one before last signal reading line 894 in last signal storage group 891. One of one before last initial set-up switch 803-1 is connected between one before last signal line 839 and first signal reading line 882 in one before last signal storage group 881. Other one of one before last initial set-up switch 803-2 is connected between one before last signal line 839 and second signal reading line 892 in last signal storage group 891. One of last initial set-up switch 804-1 is connected between last signal line 849 and first signal reading line 890 in last signal storage group 891.

In signal reading switch section, similar to initial set-up switch, a signal reading switch is called first signal reading switch when it is connected to first signal line 819. A signal reading switch is called second signal reading switch when it is connected to second signal line 829. A signal reading switch is called one before last signal reading switch when it is connected to one before last signal line 839. A signal reading switch is called last signal reading switch when it is connected to last signal line 849. Now, first initial set-up switch is connected to every signal reading line in last signal storage group 891. Second initial set-up switch is connected to every signal reading line in one before last signal storage group 881. One before last initial set-up switch is connected to every signal reading line second storage group 871. Last initial set-up switch is connected to every signal reading line in first signal storage group 861. Therefore, in last signal storage group 891, one of first signal reading switch 801-5 is connected between first signal line 819 and first signal reading line 890. Other one of first signal reading switch 801-6 is connected between first signal line 819 and second signal reading line 892. It continues on as shown with dotted line to another one of first signal reading switch 801-7 which is connected between first signal line 819 and one before last signal reading line 893. Further another one of first signal reading switch 801-8 is connected between first signal line 819 and last signal reading line 894. In one before last signal storage group 881, one of second signal reading switch 802-5 is connected between second signal line 829 and first signal reading line 882. It continues on to other one of second signal reading switch 802-7 which is connected between second signal line 829 and two before last signal reading line 883. Another one of second signal reading switch 802-8 is connected between second signal line 829 and one before last signal reading line 884. It continues on to second signal storage group 871, one of one before last signal reading switch 803-5 is connected between one before last signal line 839 and first signal reading line 872. Other one of one before last signal reading switch 802-6 is connected between one before last signal line 839 and second signal reading line 873. In first signal storage group 861, last signal reading switch 804-5 is connected between last signal line 849 and first signal reading line 862.

The operational principle of FIG. 8 can be described. A reading process consists of two steps to detect to reflective light from a discrete image of a desired resolution with a photo-sensing element to result in a photo-signal of a photo-sensing element. First step is to set up an initial condition to be ready for repeatedly reading photo-signal of a discrete image with a multiple arrays of photo-sensing elements. Second step is to read out each photo-signal from each photo-sensing element of each linear sensor array in multiple linear arrays for the same discrete image. Now, First line image which comprises of a series discrete image from first discrete image to last discrete image is one-to-one aligned to first linear sensor array such that first discrete image is aligned to first photo-sensing element 811, second discrete image is aligned to second photo-sensing element 812 and so on to last discrete image is aligned to last photo-sensing element of first linear sensor array. First step is to set up initial conditions to prepare detection of first line image by reading out photo-signals which are read with multiple linear arrays and stored into multiple signal storage groups. In the following description, all switches are off, if not indicated to turn it on.

First step comprises the steps of:

1. reading photo-signals of first linear sensor array and storing into first signal storage group 861 after first line image is one-to-one aligned to first linear sensor array by turning on:

(a) one of first initial set-up switch 801-1 and

(b) sequentially from first signal switch 812, second signal switch 816 to last signal switch of first linear sensor array and synchronizing sequentially from first signal storage switch 861-1-1 to last signal storage switch 861-1-n of first signal storage array 861-1 in first signal storage group 861 in such a manner that first signal switch 812 and first signal storage switch 862-1 are turned on at same time to store photo-signal of first photo-sensing element 811 into first signal storage device 861-1-1, followed by turning on second signal switch 816 and second signal storage switch 862-2 to store photo-signal of second photo-sensing element 815 into second signal storage device 861-1-2 and so on to store to store photo-signal of last photo-sensing element of first linear sensor array into last signal storage device 861-1-n. This concludes the storage of each photo-signal of first linear sensor array into respective each signal storage device of first signal storage array 861-1. This signal storage process is called reading and storing photo-signals of first linear sensor array into first signal storage array. Of course, the order of signal switches is not necessarily needed to be in the sequence as described. It can be other order sequence as long as there is one-to-one correspondent pair between signal switch and signal reading switch.

2. reading photo-signals of first linear sensor array and second linear sensor array and storing into second signal storage group 871 after first line image is one-to-one aligned to second linear sensor array and second line image is one-to-one aligned to first linear sensor array by turning on:

(a) other one of first initial set-up switch 801-2 and one of second initial set-up switch 802-1 and

(b) sequentially from first signal switch 812, second signal switch 816 to last signal switch of first linear sensor array and synchronizing sequentially from first signal storage switch 873-1 to last signal storage switch 873-n of second signal storage array 871-2 in second signal storage group 871 in such a manner that first signal switch 812 and first signal storage switch 873-1 are turned on at same time to store photo-signal of first photo-sensing element 811 into first signal storage device 871-2-1, followed by turning on second signal switch 816 and second signal storage switch 873-2 to store photo-signal of second photo-sensing element 815 into second signal storage device 871-2-2 and so on to store photo-signal of last photo-sensing element of first linear sensor array into last signal storage device 871-2-n. This concludes the storage of each photo-signal of first linear sensor array into respective signal storage device of second signal storage array 871-2.

(c) sequentially from first signal switch 822, second signal switch 826 to last signal switch of second linear sensor array and synchronizing sequentially from first signal storage switch 872-1 to last signal storage switch 872-n of first signal storage array 871-1 in second signal storage group 871 in such a manner that first signal switch 822 and first signal storage switch 872-1 are turned on at same time to store photo-signal of first photo-sensing element 821 into first signal storage device 871-1-1, followed by turning on second signal switch 826 and second signal storage switch 872-2 to store photo-signal of second photo-sensing element 825 into second signal storage device 871-1-2 and so on to store photo-signal of last photo-sensing element of second linear sensor array into last signal storage device 871-1-n. This concludes the storage of each photo-signal of second linear sensor array into respective each signal storage device of first signal storage array 871-1. Reading and storing of first linear sensor array into second signal storage array 871-2 and reading and storing of second linear sensor array into first signal storage array 871-1 can be at different time or at same time, depending on individual design and application which is also for each case of the rest reading and storing operations.

3. continuing on the reading and storing operation with the addition of one line image each time to read photo-signals of photo-sensing elements from first linear sensor array to one before last sensor array into one before last signal storage group 881 after first line image is one-to-one aligned to one before last linear sensor array and a line image with number of one before last is one-to-one aligned to first linear sensor array by turning on:

(a) another one of first initial set-up switch 801-3, other one of second initial set-up switch 802-2 and one of one before last initial set-up switch 803-1 and

(b) sequentially from first signal switch 812, second signal switch 816 to last signal switch of first linear sensor array and synchronizing sequentially from first signal storage switch 884-1 to last signal storage switch 884-n of one before last signal storage array 881-(m-1) in such a manner that first signal switch 812 and first signal storage switch 884-1 are turned on at same time to store photo-signal of first photo-sensing element 811 into first signal storage device 881-(m-1)-1, followed by turning on second signal switch 816 and second signal storage switch 884-2 to store photo-signal of second photo-sensing element 815 into second signal storage device 881-(m-1)-2 and so on to store photo-signal of last photo-sensing element of first linear sensor array into last signal storage device 881 (m-1)-n. This concludes the storage of each photo-signal of first linear sensor array into respective each signal storage device of one before last signal storage array 881-(m-1).

(c) sequentially from first signal switch 822, second signal switch 826 to last signal switch of second linear sensor array and synchronizing sequentially from first signal storage switch 883-1 to last signal storage switch 883-n of two before last signal storage array 881-(m-2) in such a manner that first signal switch 822 and first signal storage switch 8831 are turned on at same time to store photo-signal of first photo-sensing element 821 into first signal storage device 881-(m-2)-1, followed by turning on second signal switch 826 and second signal storage switch 883-2 to store photo-signal of second photo-sensing element 825 into second signal storage device 881-(m-2)-2 and so on to store photo-signal of last photo-sensing element of second linear sensor array into two before last signal storage device 881-(m-2)-n. This concludes the storage of each photo-signal of second linear sensor array into respective each signal storage device of two before last signal storage array 881-(m-2) and operation of reading and storing continues on to one before last linear sensor array as described in (d) next below.

(d) sequentially from first signal switch 832, second signal switch 836 to last signal switch of one before last linear sensor array and synchronizing sequentially from first signal storage switch 882-1 to last signal storage switch 882-n of first signal storage array 881-1 in such a manner that first signal switch 832 and first signal storage switch 882-1 are turned on at same time to store photo-signal of first photo-sensing element 831 into first signal storage device 881-1-1, followed by turning on second signal switch 836 and second signal storage switch 882-2 to store photo-signal of second photo-sensing element 835 into second signal storage device 881-1-2 and so on to store photo-signal of last photo-sensing element of one before last linear sensor array into last signal storage device 881-1-n. This concludes the storage of each photo-signal of one before last linear sensor array into respective each signal storage device of first signal storage array 881-1. Therefore, each photo-signal of photo-sensor element in each linear sensor array from first to one before last linear sensor array is stored into respective signal storage device in one before last signal storage group 881.

4. reading photo-signals of photo-sensing elements from first linear sensor array to last sensor array into last signal storage group 891 after first line image is one-to-one aligned to last linear sensor array and a line image with a number of last is one-to-one aligned to first linear sensor array by turning on:

(a) further another one of first initial set-up switch 801-4, another one of second initial set-up switch 802-3 and other one of one before last initial set-up switch 803-2 and one of last initial set-up switch 804-1 and

(b) sequentially from first signal switch 812, second signal switch 816 to last signal switch of first linear sensor array and synchronizing sequentially from first signal storage switch 894-1 to last signal storage switch 894-n of last signal storage array 891-m in such a manner that first signal switch 812 and first signal storage switch 894-1 are turned on at same time to store photo-signal of first photo-sensing element 811 into first signal storage device 891-m-1, followed by turning on second signal switch 816 and second signal storage switch 894-2 to store photo-signal of second photo-sensing element 815 into second signal storage device 891-m-2 and so on to store photo-signal of last photo-sensing element of first linear sensor array into last signal storage device 891-m-n. This concludes the storage of each photo-signal of first linear sensor array into respective each signal storage device of last signal storage array 891-m.

(c) sequentially from first signal switch 822, second signal switch 826 to last signal switch of second linear sensor array and synchronizing sequentially from first signal storage switch 893-1 to last signal storage switch 893-n in such a manner that first signal switch 822 and first signal storage switch 893-1 are turned on at same time to store photo-signal of first photo-sensing element 821 into first signal storage device 891-(m-1)-i, followed by turning on second signal switch 826 and second signal storage switch 893-2 to store photo-signal of second photo-sensing element 825 into second signal storage device 891-(m-1)-2 and so on to store photo-signal of last photo-sensing element of second linear sensor array into last signal storage device 891-(m-1)-n. This concludes the storage of each photo-signal of second linear sensor array into respective each signal storage device of one before last signal storage array 891-(m-1). Operation of reading and storing continues on to one before last linear sensor array as described in (d) next below.

(d) sequentially from first signal switch 832, second signal switch 836 to last signal switch of one before last linear sensor array and synchronizing sequentially from first signal storage switch 892-1 to last signal storage switch 892-n of second signal storage array 891-2 in such a manner that first signal switch 832 and first signal storage switch 882-1 are turned on at same time to store photo-signal of first photo-sensing element 831 into first signal storage device 891-2-1, followed by turning on second signal switch 836 and second signal storage switch 892-2 to store photo-signal of second photo-sensing element 835 into second signal storage device 891-2-2 and so on to store photo-signal of last photo-sensing element of one before last linear sensor array into last signal storage device 891-2-n. This concludes the storage of each photo-signal of one before last linear sensor array into respective each signal storage device of second signal storage array 891-2.

(e) sequentially from first signal switch 842, second signal switch 846 to last signal switch of last linear sensor array and synchronizing sequentially from first signal storage switch 890-1 to last signal storage switch 890-n of second signal storage array 891-2 in such a manner that first signal switch 842 and first signal storage switch 882-1 are turned on at same time to store photo-signal of first photo-sensing element 841 into first signal storage device 891-1-1, followed by turning on second signal switch 846 and second signal storage switch 890-2 to store photo-signal of second photo-sensing element 845 into second signal storage device 891-1-2 and so on to store photo-signal of last photo-sensing element of last linear sensor array into last signal storage device 891-I-n. This concludes the storage of each photo-signal of last linear sensor array into respective each signal storage device of first signal storage group 891. Therefore, each photo-signal of photo-sensor element in each linear sensor array from first to last linear sensor array is stored into respective each signal storage device in last signal storage group 891.Then, each linear sensor array is one-to-one aligned to next line image. Therefore, second line image is one-to-one aligned to last linear sensor array. Now it is ready to read out photo-signal due to each discrete image of first line image.

Therefore, it can be seen that photo-signals stored in each first signal storage array from first signal storage group 861 to last signal storage group 891 are due to first line image, photo-signals stored in each second signal storage array from second storage group 871 to last signal storage group 891 are due to second line image, photo-signals stored in each third signal storage array from third storage group to last signal storage group 891 are due to third line image, and so on to photo-signals stored in one before last signal storage array 881-(m-1) in one before last signal storage group 881 and in last signal storage group 891-(m-1) are due to line image with a number of one before last and photo-signals stored in last signal storage array 891-m in last signal storage group 891 are due to line image with a number of last. Consequently, second step is to read out photo-signals due to first line image and proceed process to detect second line image and so on to last line image. Second step comprises the steps of:

A. reading out photo-signals due to first line image with steps of:

1. reading out photo-signals in first signal storage array 861-1 in first signal storage group 861 by turning on:

(a) first output switch 865,

(b) sequentially signal storage switch from first signal storage switch 862-1 to last signal storage switch 862-n,

2. reading out photo-signals in first signal storage array 871-1 in second signal storage group 871 by turning on:

(a) first output switch 875,

(b) sequentially signal storage switch from first signal storage switch 872-1 to last signal storage switch 872-n,

3. continuing on reading out photo-signals in first signal storage array from third signal storage group to photo-signals in first signal storage array 881-1 in one before last signal storage group 881 by turning on:

(a) first output switch 885,

(b) sequentially signal storage switch from first signal storage switch 882-1 to last signal storage switch 882-n,

4. reading out photo-signals in first signal storage array 891-1 in last signal storage group 891 by turning on:

(a) first output switch 895,

(c) sequentially signal storage switch from first signal storage switch 890-1 to last signal storage switch 890-n,

5. obtaining total first photo-signal due to first discrete image of first line image which is equal to sum of read-out photo-signals of first signal storage devices from step (1) to step (4), total second photo-signal due to second discrete image of first line image which is equal to sum of read-out photo-signal of second signal storage device from step (1) to step (4) and total last photo-signal due to last discrete image of first line image which is equal to sum of read-out photo-signal of last signal storage device from step (1) to step (4).

6. clearing all signal in signal storage devices in step (1) to (4).

B. reading and storing photo-signals into signal storage devices which are cleared in step A-(6) to prepare for reading out photo-signals due to second line image with the steps of:

1. reading photo-signals of first linear sensor array and storing into signal storage devices in last signal storage group 891 by turning on:

(a) one of first signal reading switch 801-5 and

(b) sequentially from first signal switch 812, second signal switch 816 to last signal switch of first linear sensor array and synchronizing sequentially from first signal storage switch 890-1, second signal storage switch 890-2 to last signal storage switch 890-n of first signal storage array 891-1 in such a manner that first signal switch 812 and first signal storage switch 890-1 are turned on at same time to store photo-signal of first photo-sensing element 811 into first signal storage device 891 1-1, followed by turning on second signal switch 816 and second signal storage switch 890-2 at same time to store photo-signal of second photo-sensing element 815 into second signal storage device 891-1-2 and so on to store photo-signal of last photo-sensing element into last signal storage device 891-1-n to complete the photo-signal storage process to store photo-signals of first linear sensor array into first signal storage array 891-1.

2. reading photo-signals of second linear sensor array and storing into signal storage devices in one before last signal storage group 881 by turning on:

(a) one of second signal reading switch 802-5 and

(b) sequentially from first signal switch 822, second signal switch 826 to last signal switch of second linear sensor array and synchronizing sequentially from first signal storage switch 882-1, second signal storage switch 882-2 to last signal storage switch 882-n of first signal storage array 881-1 in such a manner that first signal switch 822 and first signal storage switch 882-1 are turned on at same time to store photo-signal of first photo-sensing element 821 into first signal storage device 881-1-1, followed by turning on second signal switch 826 and second signal storage switch 882-2 at same time to store photo-signal of second photo-sensing element 825 into second signal storage device 881-1-2 and so on to store photo-signal of last photo-sensing element into last signal storage device 881-1-n to complete the storage process to store photo-signals of second linear sensor array into first signal storage array 881-1.

3. continuing on the operation of reading and storing photo-signals of the rest linear sensor arrays to the step of storing photo-signals of one before last linear sensor array into signal storage devices in second signal storage group 871 by turning on:

(a) one of one before last signal reading switch 803-5 and

(b) sequentially from first signal switch 832, second signal switch 836 to last signal switch of one before last linear sensor array and synchronizing sequentially from first signal storage switch 872-1, second signal storage switch 872-2 to last signal storage switch 872-n of first signal storage array 871-1 in such a manner that first signal switch 832 and first signal storage switch 872-1 are turned on at same time to store photo-signal of first photo-sensing element 831 into first signal storage device 871-1-1, followed by turning on second signal switch 836 and second signal storage switch 872-2 at same time to store photo-signal of second photo-sensing element 825 into second signal storage device 871-1-2 and so on to store photo-signal of last photo-sensing element into last signal storage device 871-1-n to complete the storage process to store photo-signals of one before last linear sensor array into first signal storage array 871-1.

4. reading photo-signal of last linear sensor array and storing into signal storage devices in first signal storage group 861 by turning on:

(a) one of last signal reading switch 804-5 and

(b) sequentially from first signal switch 842, second signal switch 846 to last signal switch of last linear sensor array and synchronizing sequentially from first signal storage switch 862-1, second signal storage switch 862-2 to last signal storage switch 862-n of first signal storage array 861-1 in such a manner that first signal switch 842 and first signal storage switch 862-1 are turned on at same time to store photo-signal of first photo-sensing element 841 into first signal storage device 871-1-1, followed by turning on second signal switch 846 and second signal storage switch 862-2 at same time to store photo-signal of second photo-sensing element 845 into second signal storage device 861-1-2 and so on to store photo-signal of last photo-sensing element into last signal storage device 861-1-n to complete the storage process to store photo-signals of last linear sensor array into first signal storage array 871-1.

C. repeating step A to read out photo-signals due to second line image with the same steps except that second output switches 876, 886, and 896 are turned from second signal storage group 871 to last signal storage group 891 and step B to prepare for reading out photo-signals due to third line image,

D. repeating step C for the rest line images by turning correspondent output switches. It can be seen that operation to turn on output switch is sequentially from first to last output switch and is rotated from first to last output switch again after the last output switch is turned on in each signal storage group in order to complete read out photo-signals due to all line images.

Several other methods can also be applied to read out photo-signals in storage devices due to same line image. For example, one additional signal storage array is available in each signal storage group. Therefore, when reading out photo-signal due to first line image in signal storage groups, new photo-signals due to other line images can be simultaneously stored into the respective additional signal storage array in each signal storage group to speed up operation. Other method is for the case that each signal storage group has equal number of signal storage arrays, which is equal to one plus the number of signal storage arrays in last signal storage group 891. This additional one signal storage array in last signal storage group 891 is then available to read and store other photo-signals while reading out photo-signals due to first line image. Of course, the number of signal storage arrays in each signal storage group is equal to the number of initial set-up switches or signal reading switches which are connected to each signal reading lines in that signal storage group. After completion of the first step to set up initial conditions as described above, the second step comprises the steps of:

1. reading out stored photo-signals which are due to first line image by turning on

(a) first output switch 865 of first signal storage group 861, first output switch 875 of second signal storage group 871, and so on to first output switch 885 of one before last signal storage group 881 and first output switch 895 of last signal storage group 891,

(b) sequential from first signal storage switch to last signal storage switch of first signal storage array in each signal storage group,

(c) obtaining total photo-signals due to first line image which is equal to sum of photo-signal which is read out from first signal storage array in each signal storage group.

(d) clearing all photo-signals due to first line image in signal storage devices after completion of reading out operation.

2. reading photo-signals of photo-sensing elements of each linear sensor array in multiple linear sensor array and stored into next available signal storage array in each signal storage group respectively at same time while reading out photo-signals due to first line image.

3. repeating step 1 and 2 to read out photo-signals due to second line image and store photo-signals of photo-sensing elements of each linear sensor array in multiple linear sensor arrays into available respective signal storage array in each signal storage group,

4. repeating step 3 for the rest line images.

One advantage of FIG. 8 is that various different resolutions can be obtained for a given sensor array design with a modification of the wafer process. For example, when sensor array is designed for 1200 dpi resolution, then 600 dpi resolution can be obtained by connecting two neighboring signal switches together in wafer processing and adding outputs from two neighboring linear sensor arrays to result in an output for 600 dpi. For example, in FIG. 8, first signal switch 812 and second signal switch 816 are connected together, first signal switch 812 and second signal switch 816 are connected together, and so on. Similar connections are made on signal switches for the rest linear sensor arrays. Therefore, first and second photo-sensing elements 811 and 815 are turned on at same time to result in one photo-signal as photo-signal of first pixel for a resolution of 600 dpi application. The total photo-signal of first pixel for 600 dpi is sum of photo-signal of first pixel from first linear sensor array and photo-signal of first pixel from second linear sensor array. Similar process is followed to obtain total photo-signal of the rest pixels. With the same method, one can select neighboring 4 photo-sensing elements and 4 neighboring linear sensor arrays to obtain a resolution of 300 dpi. It can be seen that one can select a desired number to achieve a desired resolution. Another advantage is to obtain different photo-signals at same time by either coating a desired color pattern on multiple on multiple linear sensor arrays or by the incident of color light pattern an line images which are one-to-one aligned to respective line sensor arrays. Those who are skillful in the field can easily modify to satisfy a desired application.

The preferred embodiments of this invention have been described in detail. The scope and the spirits of this invention are not limited by the preferred embodiments described above. It is set by the claims listed below.

What is claimed is

1. a technique to assemble a CIS (Contact Image Sensor) module, employing the use of components of:
(a) an alignment plate which has an alignment array of light-through structures which are one-to-one aligned to a sensor array of a photo-sensing elements, including photo-diodes, photo-transistors, charge coupled devices, on a sensor IC chip which is used to butt to form a linear sensor array,
(b) a light-guide plate which has a light-guide array of light-guide structures which are one-to-one aligned to said light-through structures at one end and one-to-one aligned to said resolution definition structures at the other end.
(c) a resolution plate which has a resolution array of said resolution-definition structures.
in such a configuration of said components that said alignment plate is between said sensor IC chip and said light-guide plate which is between said alignment plate and said resolution plate which is aligned to a line image which is an linear image array of a discrete image which upon an incident of a light source has a reflective light to pass through an aligned one of said resolution-definition structures which are one-to-one aligned to said linear image array to other aligned one of said light-guide structures which guides said reflective light to another one of said light-through structures which transfers said reflective light further to other another aligned one of said photo-sensing elements of said sensor array to result in a photo-signal of said photo-sensing element of said sensor array.

2. a technique in claim 1 wherein a separate said alignment plate is made on said sensor IC chip at wafer level during manufacturing of said sensor IC chip.

3. a technique in claim 1 wherein said alignment plate is an integrated portion of said light-guide plate by integrating said light-through structures and said light-guide structures together where said light-through structures of said alignment plate are one-to-one aligned to said light-guide structures.

4. a technique in claim 1 wherein each one of said resolution-definition structures is in a cavity structure which has a dimension to allow only said reflective light from said discrete image with a size of said desired resolution pass through respective said aligned one of said resolution-definition structures to said other aligned one of said light-guide structures.

5. a technique in claim 1 wherein said CIS module has a plural number, including 1, of said linear sensor arrays, other plural number, including 1, of said alignment arrays, another plural number, including 1, of said light-guide arrays, and further another plural number, including 1, of said resolution arrays.

6. a technique in claim 1 wherein said photo-signal of said photo-sensing element, including an electronic device, in a linear sensor array of said photo-sensing elements is read to obtain a photo-response of said photo-sensing element, which is repeatedly read to obtain total photo-response of said photo-sensing element by employing the use of a signal reading section, comprising the components of:
(a) an amplifier circuits block which has output terminal, signal input terminal, reference input terminal such that said photo-signal is applied at said signal input terminal through a signal switch which is connected between said photo-sensing element and a common line which is connected to said signal input terminal,
(b) an signal block which has a read signal storage stage which comprises read signal storage switch, read signal storage device and read signal reading switch with a connection among said read signal storage switch, said read signal storage device and said read signal reading switch in such a manner that said read signal storage switch and said read signal storage device are connected in series between said output terminal and a common ground such that said read signal storage switch is connected to said output terminal and said read signal storage device is connected to said common ground and said read signal reading switch that is connected between said signal input terminal and common connection point of said read signal storage switch and said read signal storage device so that said read signal storage device stores read photo-signal of said photo-sensing element and has plural number, including 1, of enhanced read signal storage stages which each of said enhanced read signal storage stages comprises enhanced read signal storage switch, enhanced read signal storage device and enhanced read signal reading switch with other connection among said enhanced read signal storage switch, said enhanced read signal storage device and said enhanced read signal reading switch in such a manner that said enhanced read signal storage switch and said enhanced read signal storage device are connected in series between said output terminal and said common ground such that said enhanced read signal storage switch is connected to said output terminal and said enhanced read signal storage device is connected to said common ground and said enhanced read signal reading switch which is connected between said signal input terminal and other common connection of said enhanced read signal storage switch and said enhanced read signal storage device so that said enhanced read signal storage device of first said enhanced read signal storage stage stores first enhanced read photo-signal which is obtained by reading said read photo-signal of said photo-sensing element, said enhanced read signal storage device of second said enhanced read signal storage stage stores second enhanced read photo-signal which is obtained by reading said first enhanced read photo-signal, said enhanced read signal storage device of third said enhanced read signal storage stage stores third enhanced read photo-signal which is obtained by reading said second enhanced read photo-signal, to said enhanced read signal storage device of last said enhanced read signal storage stage stores last enhanced read photo-signal which is obtained by reading said one before said last enhanced read photo-signal.
(c) a reference block which has other plural number, including 1, of reference storage stages which each of said other plural number of reference storage stages comprises reference storage switch, reference storage device and reference reading switch with another connection among said reference storage switch, said reference storage device and said reference reading switch in such a manner that said reference storage switch and said reference storage device are connected in series such that said reference storage switch is connected to said output terminal and said reference storage device is connected to said common ground and said reference reading switch is connected between an input resistor which is connected to said reference terminal and another common connection point of said reference storage switch and said reference storage device so that first said reference storage stage which stores first reference to be subtracted out from said photo-signal of said photo-sensing element, second said reference storage stage which stores second reference to be subtracted out from said read photo-signal which is stored in said read signal storage stage, third said reference storage stage which stores third reference to be subtracted out from said first enhanced read photo-signal which is stored in said first said enhanced read signal storage stage, to other last said reference storage stage which stores other last reference to be subtracted out from said last enhanced read photo-signal which is stored in said last said enhanced read signal storage stage.
(d) an output block which has another plural number, including 1, of output stages which include first output stage to send out said read photo-signal through said first output stage which has first output switch which is connected between said output terminal and first output post, second output stage to send out said first enhanced read photo-signal through said second output stage which has second output switch which is connected between said output terminal and second output post, third output stage to send out said second enhanced read photo-signal through said third output stage which has third output switch which is connected between said output terminal and third output post, to one after said last output stage to send out said last enhanced read photo-signal through said one after said last output stage which has one after said last output switch which is connected between said output terminal and one after said last output post.

7. a technique in claim 6 wherein said photo-response of said photo-sensing element is enhanced to achieve total photo-response of said photo-sensing element with a method which comprising the steps of:
(1) storing said first reference into said first said reference storage stage by turning on said reference storage switch in said first said reference storage stage switch,
(2) storing said second reference into said second said reference storage stage by turning on said reference reading switch of said first said reference storage stage and said read signal storage switch, followed by turning on said read signal reading switch and said reference storage switch of said second said reference storage stage,
(3) storing said third reference into said third said reference storage stage by turning on said reference reading switch of said second said reference storage stage and said enhanced read signal storage switch of said first said enhanced read signal storage, followed by turning on said first said enhanced read signal reading switch and said reference storage switch of said third said reference storage stage,
(4) continuing on till storing said other last reference into said other last reference storage stage by turning on said reference reading switch of said one before said other last reference storage stage and said enhanced read signal storage switch of said last said enhanced read signal storage, followed by turning on said last said enhanced read signal reading switch and said reference storage switch of said other last said reference storage stage,
(5) reading said photo-signal of first said photo-sensing element without light exposure to said linear sensor array to result in dark signal of said first said photo-sensing element which is sent out to said first output post and simultaneously stored into said read signal storage device by turning on first said signal switch, said reference reading switch of said first said reference storage stage, said read signal storage switch and said first output switch,
(6) reading said dark signal to result in first enhanced dark signal which is sent out to said second output post and simultaneously stored into said enhanced read signal storage device of said first said enhanced read signal storage stage by turning on said read signal reading switch, said reference reading switch of said second said reference storage stage, said enhanced read signal storage switch of said first said enhanced read signal storage stage, and said second output switch,
(7) reading said first enhance dark to result in second enhanced dark signal which is sent out to said third output post and simultaneously stored into said enhanced read signal storage device of said second said enhanced read signal storage stage by turning on first said enhanced read signal reading switch, said reference reading switch of said third said reference storage stage, said enhanced read signal storage switch of said second said enhanced read signal storage stage, and said third output switch,
(8) continuing on reading to obtain third enhanced dark signal to the last enhanced dark signal which is respectively sent out and simultaneously stored into said third said enhanced read signal storage stage to said last said enhanced read signal storage stage respectively,
(9) clearing said dark signal, said first enhanced dark signal, said second enhanced dark signal and said third enhanced dark signal to said last enhanced dark signal for said first said photo-sensing element,
(10) repeating said step of (5) to said step of (9) to obtain said dark signal, said first enhanced dark signal, said second enhanced dark signal and said third enhanced dark signal to said last enhanced dark signal for each said photo-sensing element from second to last said photo-sensing element in said linear sensor array,
(11) exposing light to said linear sensor array at a desired level of the intensity for a desired period of time,
(12) reading said photo-signal of said first said photo-sensing element to result in light signal of said photo-sensing element which is sent out to said first output post and simultaneously stored into said read signal storage device by turning on first said signal switch, said reference reading switch of said first said reference storage stage, said read signal storage switch and said first output switch,
(13) reading said light signal to result in first enhanced light signal which is sent out to said second output post and simultaneously stored into said enhanced read signal storage device of said first said enhanced read signal storage stage by turning on said read signal reading switch, said reference reading switch of said second said reference storage stage, said enhanced read signal storage switch of said first said enhanced read signal storage stage, and said second output switch,
(14) reading said first enhanced light signal to result in second light signal which is sent out to said third output post and simultaneously stored into said enhanced read signal storage device of said second said enhanced read signal storage stage by turning on first said enhanced read signal reading switch, said reference reading switch of said third said reference storage stage, said enhanced read signal storage switch of said second said enhanced read signal storage stage, and said third output switch,
(15) continuing on to obtain third enhanced light signal to last enhanced light signal which is respectively sent out and simultaneously stored into said third said enhanced read signal storage stage to said last said enhanced read signal storage stage respectively,
(16) clearing said light signal, said first enhanced light signal, said second enhanced light signal, said third enhanced light signal to said last enhanced light signal for said first said photo-sensing element,
(17) repeating said step of (12) to said step of (16) to obtain said light signal, said first enhanced light signal, said second enhanced light signal, said third enhanced light signal to said last enhanced light signal for second said photo-sensing element to last said photo-sensing element in said linear sensor array,
(18) obtaining said photo-response of said first said photo-sensing element by subtracting out said dark signal from said light signal, first enhanced photo-response of said first said photo-sensing element by subtracting out said first enhanced dark signal from said first enhanced light signal, second enhanced photo-response of said first said photo-sensing element by subtracting out said second enhanced dark signal from said second enhanced light signal, and third enhanced photo-response to last enhanced photo-response of said first said photo-sensing element by subtracting out said third enhanced dark signal from said third enhanced light signal to by subtracting out said last enhanced dark signal from said last enhanced light signal respectively,
(19) obtaining said total photo-response of said first said photo-sensing element which is said photo-response, said first enhanced photo-response, said second enhanced photo-response, each one of said third enhanced photo-response to said last photo-response, sum of a selected number of items from said photo-response, said first enhanced photo-response, said second enhanced photo-response, and each one from said third enhanced photo-response to said last photo-response.
(20) repeating said step of (18) and said step of (19) to obtain said photo-response and said total photo-response for said second said photo-sensing element to said last said photo-sensing element in said linear sensor array,

8. a technique in claim 6 wherein said photo-response of said photo-sensing element is enhanced to achieve total photo-response of said photo-sensing element with a method which comprising the steps of:
(1) reading said photo-signal of said photo-sensing element without light exposure to said linear sensor array to result in dark signal of each said photo-sensing element from first to last said photo-sensing element in said linear sensor array by turning on respective said signal switch such that said dark signal of said each said photo-sensing element is sent out and simultaneously used to obtain a mean value of said dark signal from a desired number of said photo-sensing elements, which is store into said first reference storage device by turning on said reference storage switch in first said reference storage stage,
(2) storing said second reference into said second said reference storage stage by turning on said reference reading switch of said first said reference storage stage and said read signal storage switch, followed by turning on said read signal reading switch and said reference storage switch of said second said reference storage stage,
(3) storing said third reference into said third said reference storage stage by turning on said reference reading switch of said second said reference storage stage and said enhanced read signal storage switch of said first said enhanced read signal storage, followed by turning on said first said enhanced read signal reading switch and said reference storage switch of said third said reference storage stage,
(4) continuing on till storing said other last reference into said other last reference storage stage by turning on said reference reading switch of said one before said other last reference storage stage and said enhanced read signal storage switch of said last said enhanced read signal storage, followed by turning on said last said enhanced read signal reading switch and said reference storage switch of said other last said reference storage stage,
(5) exposing light to said linear sensor array at a desired level of the intensity for a desired period of time,
(6) reading said photo-signal of said first said photo-sensing element to result in a photo-response of said photo-sensing element which is sent out to said first output post and simultaneously stored into said read signal storage device by turning on first said signal switch, said reference reading switch of said first said reference storage stage, said read signal storage switch and said first output switch,
(7) reading said photo-response to result in first enhanced photo-response which is sent out to said second output post and simultaneously stored into said enhanced read signal storage device of said first said enhanced read signal storage stage by turning on said read signal reading switch, said reference reading switch of said second said reference storage stage, said enhanced read signal storage switch of said first said enhanced read signal storage stage, and said second output switch,
(8) reading said first enhanced photo-response to result in second enhanced photo-response which is sent out to said third output post and simultaneously stored into said enhanced read signal storage device of said second said enhanced read signal storage stage by turning on first said enhanced read signal reading switch, said reference reading switch of said third said reference storage stage, said enhanced read signal storage switch of said second said enhanced read signal storage stage, and said third output switch,
(9) continuing on to obtain third enhanced photo-response to last enhanced photo-response which is respectively sent out and simultaneously stored into said third said enhanced read signal storage stage to said last said enhanced read signal storage stage respectively,
(10) clearing said photo-response, said first enhanced photo-response, said second enhanced photo-response, said third enhanced photo-response to said last enhanced photo-response for said first said photo-sensing element, (11) repeating said step of (6) to said step of (10) to obtain said photo-response, said first enhanced photo-response, said second enhanced photo-response, said third enhanced photo-response to said last enhanced photo-response for second said photo-sensing element to last said photo-sensing element in said linear sensor array,
(12) obtaining said total photo-response of said first said photo-sensing element which is said photo-response, said first enhanced photo-response, said second enhanced photo-response, each one of said third enhanced photo-response to said last photo-response, sum of a selected number of items from said photo-response, said first enhanced photo-response, said second enhanced photo-response, and each one from said third enhanced photo-response to said last photo-response.

9. a technique in claim 6 wherein a gain in said reference storage stage is designed to be equal 1.

10. a technique in claim 1 wherein a desired number of said photo-sensing elements are used to form said linear sensor array which is used to form multiple linear sensor arrays to obtain total photo-response of said photo-sensing element, employing the use of components which comprises of:
(a) a signal storage device which is used to store said photo-signal and is used to form a signal storage array which is used to form plural, including 1, signal storage arrays which form a signal storage group which is used to form said multiple signal storage groups,
(b) a signal storage switch which is connected between said signal storage device of said signal storage array and signal reading line which is connected to each said signal storage device of said signal storage array such that each said signal storage group has said plural signal reading lines such that first said signal storage array has first said signal reading line, second said signal storage array has second said signal reading line, third said signal storage array has third said signal reading line, one before last said signal storage array has one before last signal reading line, and last said signal storage array has last signal reading line,
(c) a signal switch which is connected between said photo-sensing element of said linear sensor array and a common line which is connected to each said photo-sensing element of said linear sensor array and to an output circuit block which is connected between said common line and a signal line such that first said linear sensor array has first said signal line, second said linear sensor array has second said signal line, till one before other last said linear sensor array has one before other last said signal line and other last said linear sensor array has other last said signal line.
(d) an initial set-up switch which is connected between said signal line of said linear sensor array and said signal reading line of said signal storage array in such a manner that first said initial set-up switch is connected between said first said signal line and each said signal reading line which includes said first said signal reading line in first said signal storage group, said second said signal reading line in second said signal storage group, said one before said other last signal reading line in one before said other last said signal storage group and said other last said signal reading line in said other last said signal storage group, second said initial set-up switch is connected between said second said signal line and each said signal reading line which includes said first said signal reading line in said second signal storage group, said second signal reading line in said third signal storage group, said two before said other last signal reading line in said one before said other last said signal storage group and said one before said other last said signal reading line in said other last signal storage group, one before said other last initial set-up switch is connected between said one before said other last said signal line and each of said first said signal reading line in said one before said other last signal storage group and said second said signal reading line in said other last signal storage group, and other last said initial setup switch is connected between said other last said signal line and said first said signal reading line in said other last said signal storage group.
(e) a signal reading switch which is connected between said signal line and said signal reading line in such a manner that first said signal reading switch is connected between said first signal line and each one from said first signal reading line to said other last said signal reading line in said other last said signal storage group, second said signal reading switch is connected between said second signal line and each one from said first signal reading line to said other last signal reading line in said one before said other last said signal storage group, one before said other last said signal reading switch is connected between said one before said other last said signal line and each one from said first signal reading line to said other last signal reading line in said second said signal storage group and other last said signal reading switch is connected between said other last said signal line and each one from said first signal reading line to said other last signal reading line in said first signal storage group.
(f) an output switch which is connected between said signal reading line and an output post.

11. a technique in claim 10 wherein said output circuit block is disabled by directly connecting said common line and said signal line together.

12. a technique in claim 10 wherein said total photo-response is obtained with a use of a number of said signal storage arrays of said each said signal storage group more than said initial set-up switches which are connected to said each signal storage group, comprising the steps of:
I. starting to set up initial conditions, comprising the steps of:
(1) storing said photo-signals of said photo-sensing elements of first said linear sensor array into said signal storage devices of said first signal storage array in said first signal storage group by turning on:
(a) said signal switches of said first linear sensor array,
(b) said first said initial set-up switch which is connected between said first said signal line and said first said signal reading line in said first said signal storage group,
(c) said first said signal storage switches in said first said signal storage group in synchronization to said step I-(1)-(a),
(2) storing said photo-signals of said photo-sensing elements of said first said linear sensor array into said signal storage devices of said second signal storage array in said second signal storage group and said photo-signals of said photo-sensing elements of said second said linear sensor array into said signal storage devices of said first signal storage array in said second signal storage group by turning on:
(a) said first said signal switches,
(b) said first said initial set-up switch which is connected between said first said signal line and said second said signal reading line in said second said signal storage group,
(c) said second said signal storage switches of said second said signal storage array in said second said signal storage group in synchronization to said step I-(2)-(a),
(d) said second said signal switches
(e) said second said initial set-up switch which is connected between said second said signal line and said first said signal reading line in said second said signal storage group,
(f) said first said signal storage switches of said first said signal storage array in said second said signal storage group in synchronization to said step I-(2)-(d),
(3) repeating said steps I-(2) by adding third said linear sensor array to store said photo-signals of photo-sensing elements of said first said linear sensor array into said signal storage devices of said third said signal storage array in said third said signal storage group, said photo-signals of photo-sensing elements of said second said linear sensor array into said signal storage devices of said second said signal storage array in said third said signal storage group and said photo-signals of photo-sensing elements of said third said linear sensor array into said signal storage devices of said first said signal storage array in said third said signal storage group, and continuing on said repeating said step I-(2) by adding one more said linear sensor array each time to store each said photo-signals of said photo-sensing element of each said linear sensor array into respective said signal storage devices of respective said signal storage array in respective said signal storage group until said photo-signals of said photo-sensing elements of every said linear sensor array of said multiple linear sensor arrays are stored into said signal storage devices in said other last said signal storage group in such a manner that said photo-signals of said photo-sensing elements of said first said linear sensor array are stored into said signal storage devices of said other last said signal storage array in said other last said signal storage group, said photo-signals of said photo-sensing elements of said second said linear sensor array are stored into said signal storage devices of said one before said other last said signal storage array in said other last said signal storage group, said photo-signals of said photo-sensing elements of said one before said other last said linear sensor array are stored into said signal storage devices of said second said signal storage array in said other last said signal storage group, and said photo-signals of said photo-sensing elements of said other last said linear sensor array are stored into said signal storage devices of said first said signal storage array in said other last said signal storage group,
II. starting an operation to read out said photo-signals which are stored in said signal storage devices, comprising the steps of:
(A) reading out said photo-signals of first said line image, comprising the step of
(1) reading out said photo-signals which are stored in said signal storage devices of said first said signal storage array in said each said signal storage group to respective said output post which is connected to respective said signal reading line by turning on said output switch which is connected to said first said signal reading line in said each said signal storage group and by turning on said first said signal storage switches of said first said signal storage array in said each said signal storage group,
(2) after completion of said reading out, clearing said photo-signals of said signal storage devices of each said first signal storage array in said each said storage group at said step II-(A)-(1),
(B) reading out said photo-signals of second said line image, comprising the step of:
(a) storing said photo-signals of said photo-sensing elements of each said linear sensor array in said multiple linear sensor arrays into respective said signal storage devices of said signal storage array in respective said signal storage group, comprising the steps of:
(1) storing said photo-signals of said photo-sensing elements of said first said linear sensor array into one after other last said signal storage array in said other last said signal storage group by turning on:
(a) said signal switches of said first said linear sensor array,
(b) said first said signal reading switch which is connected to one after said signal reading line in said other last said signal storage group,
(c) said signal storage switches of said one after said other last said signal storage array in said other last said signal storage group,
(2) storing said photo-signals of said photo-sensing elements of said second said linear sensor array into said other last said signal storage array in said one before said other last said signal storage group by turning on:
(a) said signal switches of said second linear sensor array,
(b) said second said signal reading switch which is connected to said other last said signal reading line in said one before said other last said signal storage group,
(c) said other last said signal storage switches in said one before said other last said signal storage group,
(3) continuing on storing said photo-signals of said photo-sensing elements from said third sensor array to said one before said other last said linear sensor array such that said photo-signals of said photo-sensing elements of said one before said other last said linear sensor array are stored into said third said signal storage array in said second said signal storage group by turning on:
(a) said one before said other last signal switches of said one before said other last said linear sensor array,
(b) said one before said other last said signal reading switch which is connected to said third said signal reading line in said second said signal storage group,
(c) said third said signal storage switches in said second said signal storage group,
(4) storing said photo-signals of said photo-sensing elements of said other last said linear sensor array into said second said signal storage array in said first said signal storage group by turning on:
(a) said other last signal switches of said other last said linear sensor array,
(b) said other last said signal reading switch which is connected to said second signal reading line in said first said signal storage group,
(c) said second said signal storage switches in said first said signal storage group,
(b) reading out said photo-signals for second said line image, comprising the steps of:
(1) reading out said photo-signals which are stored in said signal storage devices of each said second said signal storage array in said each said signal storage group to respective said output post which is connected to respective said signal reading line by turning on said output switch which is connected to said second said signal reading line in said each said signal storage group and by turning on said second said signal storage switches of said second said signal storage array in said each said signal storage group,
(2) after completion of said reading out, clearing said photo-signals in said signal storage devices of each said signal storage array in said each said signal storage group for said reading out said photo-signal for said second said line image at said step II-(B)-(b)(1),
C. repeating said steps II-(B)-(a) for third said line image to store said photo-signals of said photo-sensing elements of said first said linear sensor array into said first said signal storage array in said other last said signal storage group, said photo-signals of said photo-sensing elements of said second said linear sensor array into one after said other last said signal storage array in said one before said last said signal storage group, said photo-signals of said photo-sensing elements of said one before said other last linear sensor array into fourth said signal storage array in said second signal storage group and said photo-signals of said photo-sensing elements of said other last linear sensor array into third said signal storage array of said first signal storage group, following by repeating said step II-(B)-(b) to read out said photo-signals of said photo-sensing elements for said third said line image,
(D). repeating said step II-(D) to read out photo-signal signals for each one of the rest of said line images in such a manner that for said each said signal storage group, said photo-signals of said photo-sensing elements are stored into said first said signal storage array after said number said storage array has been used to store said photo-signals.
(E) reading said photo-signal under the conditions which no light is exposed to said photo-sensing element to result in dark signal, and light is exposed to said photo-sensing element to result in light signal such that said light signal minus said dark signal leaves a photo-response of said photo-sensing element so that said total photo-response is equal to sum of said photo-response which is obtained from said reading out said photo-signals of said photo-sensing element from said signal storage array in said each signal storage group for same said discrete image in each said line image.

13. a technique in claim 10 wherein said total photo-response is obtained with a use of a number of signal storage arrays of said each said signal storage group equal to total number of said initial set-up switches which are connected to said each signal storage group, comprising the steps of:
I. starting to set up initial conditions, comprising the steps of:
(1) storing said photo-signals of said photo-sensing elements of first said linear sensor array into said signal storage devices of said first signal storage array in said first signal storage group by turning on:
(a) said signal switches of said first linear sensor array,
(b) said first said initial set-up switch which is connected between said first said signal line and said first said signal reading line in said first said signal storage group,
(d) said first said signal storage switches in said first said signal storage group in synchronization to said step I-(1)-(a),
(2) storing said photo-signals of said photo-sensing elements of said first said linear sensor array into said signal storage devices of said second signal storage array in said second signal storage group and said photo-signals of said photo-sensing elements of said second said linear sensor array into said signal storage devices of said first signal storage array in said second signal storage group by turning on:
(a) said first said signal switches,
(b) said first said initial set-up switch which is connected between said first said signal line and said second said signal reading line in said second said signal storage group,
(c) said second said signal storage switches of said second said signal storage array in said second said signal storage group in synchronization to said step I-(2)-(a),
(d) said second said signal switches
(e) said second said initial set-up switch which is connected between said second said signal line and said first said signal reading line in said second said signal storage group,
(f) said first said signal storage switches of said first said signal storage array in said second said signal storage group in synchronization to said step I-(2)-(d),
(3) repeating said steps I-(2) by adding third said linear sensor array to store said photo-signals of photo-sensing elements of said first said linear sensor array into said signal storage devices of said third said signal storage array in said third said signal storage group, said photo-signals of photo-sensing elements of said second said linear sensor array into said signal storage devices of said second said signal storage array in said third said signal storage group and said photo-signals of photo-sensing elements of said third said linear sensor array into said signal storage devices of said first said signal storage array in said third said signal storage group, and continuing on said repeating said step I-(2) by adding one more said linear sensor array each time to store each said photo-signals of said photo-sensing element of each said linear sensor array into respective said signal storage devices of respective said signal storage array in respective said signal storage group until said photo-signals of said photo-sensing elements of every said linear sensor array of said multiple linear sensor arrays are stored into said signal storage devices in said other last said signal storage group in such a manner that said photo-signals of said photo-sensing elements of said first said linear sensor array are stored into said signal storage devices of said other last said signal storage array in said other last said signal storage group, said photo-signals of said photo-sensing elements of said second said linear sensor array are stored into said signal storage devices of said one before said other last said signal storage array in said other last said signal storage group, said photo-signals of said photo-sensing elements of said one before said other last said linear sensor array are stored into said signal storage devices of said second said signal storage array in said other last said signal storage group, and said photo-signals of said photo-sensing elements of said other last said linear sensor array are stored into said signal storage devices of said first said signal storage array in said other last said signal storage group,
II. starting an operation to read out said photo-signals which are stored in said signal storage devices, comprising the steps of:
(A) reading out said photo-signals of first said line image, comprising the step of.
(1) reading out said photo-signals which are stored in said signal storage devices of said first said signal storage array in said each said signal storage group to respective said output post which is connected to respective said signal reading line by turning on said output switch which is connected to said first said signal reading line in said each said signal storage group and by turning on said first said signal storage switches of said first said signal storage array in said each said signal storage group,
(2) after completion of said reading out, clearing said photo-signals of said signal storage devices of each said first signal storage array in said each said storage group at said step II-(A)-(1),
(B) reading out said photo-signals of second said line image, comprising the step of:
(a) storing said photo-signals of said photo-sensing elements of each said linear sensor array in said multiple linear sensor arrays into respective said signal storage devices of said signal storage array in respective said signal storage group, comprising the steps of:
(1) storing said photo-signals of said photo-sensing elements of said first said linear sensor array into said first said signal storage array in said other last said signal storage group by turning on:
(a) said signal switches of said first said linear sensor array,
(b) said first said signal reading switch which is connected to said first said signal reading line in said other last said signal storage group,
(b) said signal storage switches of said first said signal storage array in said other last said signal storage group,
(2) storing said photo-signals of said photo-sensing elements of said second said linear sensor array into said first said signal storage array in said one before said other last said signal storage group by turning on:
(a) said second signal switches of said second linear sensor array,
(b) said second said signal reading switch which is connected to said first said signal reading line in said one before said other last said signal storage group,
(c) said signal storage switches of said first said signal storage array in said one before said other last said signal storage group,
(3) continuing on storing said photo-signals of said photo-sensing elements into said first signal storage array in respective said signal storage group till said photo-signals of said photo-sensing elements of said one before said other last said linear sensor array are stored into said first said signal storage array in said second said signal storage group by turning on:
(a) said signal switches of said one before said other last said linear sensor array,
(b) said one before said other last said signal reading switch which is connected to said first said signal reading line in said second said signal storage group,
(c) said signal storage switches of said first said signal storage array in said second said signal storage group,
(4) storing said photo-signals of said photo-sensing elements of said other last said linear sensor array into said first said signal storage array in said first said signal storage group by turning on:
(a) said signal switches of said other last said linear sensor array,
(b) said other last said signal reading switch which is connected to said first signal reading line in said first said signal storage group,
(d) said signal storage switches of said first said signal storage array in said first said signal storage group,
(b) reading out said photo-signals for second said line image, comprising the steps of:
(1) reading out said photo-signals which are stored in said signal storage devices of said first said signal storage array in said first signal storage group by turning on:
(a) said first output switch which is connected between said first output post and said first said signal reading line,
(b) said signal storage switches of said first said signal storage array in said first said signal storage group,
(2) reading out said photo-signals which are stored in said signal storage devices of each said second said signal storage array in said signal storage group from said second said signal storage group to said other last said signal storage group to respective said output post which is connected to respective said signal reading line by turning on:
(a) each said second output switch which is respectively connected to said each said second said signal reading line in respective said each said signal storage group,
(b) said signal storage switches of said second said signal storage array in said each said signal storage group,
(3) after completion of said reading out, clearing said photo-signals in said signal storage devices of each said signal storage array in said each said signal storage group for said reading out said photo-signal for said second said line image at said steps II-(B)-(b)-(1) and -(2),
C. repeating said step II-(B)-(a) for third said line image to store said photo-signals of said photo-sensing elements of said first said linear sensor array into said second said signal storage array in said other last said signal storage group, said photo-signals of said photo-sensing elements of said second said linear sensor array into said second said signal storage array in said one before said last said signal storage group, said photo-signals of said photo-sensing elements of said one before said other last linear sensor array into said second said signal storage array in said second signal storage group and said photo-signals of said photo-sensing elements of said other last linear sensor array into said first said signal storage array in said first signal storage group, following by repeating said step II-(B)-(b) to read out said photo-signals of said photo-sensing elements for said third said line image from said signal storage arrays which include said first said signal storage array in said first signal storage group, said first said signal storage array in said second signal storage group, said third signal storage array in said signal storage group from said third signal storage group to said other last said signal storage group,
(D) repeating said step II-(D) to read out photo-signal signals for each one of the rest of said line images in such a manner that for each said signal storage group, said photo-signals of said photo-sensing elements are stored into said first said signal storage array after said number said signal storage array has been used to store said photo-signals.
(E) reading said photo-signal under the conditions which no light is exposed to said photo-sensing element to result in dark signal, and light is exposed to said photo-sensing element to result in light signal such that said light signal minus said dark signal leaves a photo-response of said photo-sensing element so that said total photo-response is equal to sum of said photo-responses which are obtained from said reading out said photo-signals of said photo-sensing element from said signal storage array in said each signal storage group for same said discrete image in each said line image.

14. a technique in claims 10 wherein different color signals of said photo-sensing elements are obtained by coating a pattern of color filters on said photo-sensing elements in said multiple linear sensor arrays according to said different color signals.

15. a technique in claim 10 wherein different color signals of said photo-sensing elements are obtained by a desired color light pattern which is designed according to said different color signals.

16. a technique in claim 10 wherein a selected number of said signal switches are turned on simultaneously to achieve different resolution.

17. a technique in claim 10 wherein a selected number of said signal storage switches are turned on simultaneously to achieve a different resolution.
